(19) United States
(12) Patent Application Publication
(10) Pub. No.: US 2024/0394451 A1
(43) Pub. Date: Nov. 28, 2024

(54) SELF-ADAPTING ANALOG CIRCUIT DESIGN METHOD AND SYSTEM

(71) Applicant: ANALOG INTELLIGENT DESIGN INC., Morgan Hill, CA (US)

(72) Inventors: Zia Abbas, Hyderabad (IN); Khanh Minh Le, Morgan Hill, CA (US); Koushik De, Hyderabad (IN); Deepthi Amuru, Hyderabad (IN)

(21) Appl. No.: 18/202,819

(22) Filed: May 26, 2023

(51) Int. Cl. G06F 30/367; G06F 30/373

(52) U.S. Cl. CPC G06F 30/367; G06F 30/373

(57) ABSTRACT

A method and system based on machine learning to create self-adapting analog circuits adapted to change their internal components on-the-fly in response to changes in process, voltage, and temperature to re-tune the electrical characteristics back to nominal specified values is disclose. The method and system herein comprise of designing the analog circuit, generating simulation data for machine learning, creating a full query database, creating and training, using simulation results, a machine learning (ML) model of the circuit and applying the ML model to infer the required changes to internal components of the analog circuit in response to changes in P, V, and T conditions. With this method and system, evaluation of the adverse effects of PVT changes, decision on internal circuit changes, and realization of requisite design changes are performed by the computer system solely within a ML data domain, in a time and resource efficient manner.

### CROSS-REFERENCE TO RELATED APPLICATION

This patent application claims the benefit of U.S. Pat. No. 11,416,664 granted Aug. 16, 2022, the complete disclosure of which, in its entirety, is herein incorporated by reference.

### BACKGROUND

### Technical Field

The embodiments herein generally relate to self-adapting analog integrated circuits, and more particularly, to a method and system to create self-adapting analog circuits based on machine learning models that change their internal components on-the-fly.

### Description of the Related Art

Typically, the behavior of an analog circuit is described by its specifications that include several electrical characteristics such as gain, bandwidth, current consumption, accuracy, distortion, input impedance, input offset voltage, output impedance, power supply rejection ratio, etc. Any changes in environmental conditions like voltage and temperature, and manufacturing variances cause such characteristics to shift away from their nominal values that are specified for room temperature, nominal supply voltage, and typical process corner.

Conventionally, analog circuits are designed to cover a wide range of extreme manufacturing variances characterized by P and environmental conditions like supply voltage V and chip temperature T and still meet their specifications, even though such extreme conditions rarely occur in practice. However, such method results in inefficient designs that are larger in die area, consume more power, and have undesirable electrical specifications. Furthermore, any design change to the analog circuit must be decided after the circuit designer has run through a large number of simulations covering most if not all the above range of PVT conditions to ensure that the circuit meets the specifications in every condition. The long run time, a large amount of compute resources required for simulation, and the design analysis work together create the largest bottleneck of the current method and system.

The current analog circuit design system and method face several practical problems. The first problem being analog circuits still have their electrical characteristics vary widely over the range of process, voltage, and temperature limits. For CMOS Complementary Metal Oxide Semiconductor technologies, P which is usually reflected by the electrical characteristics of the NMOS and PMOS transistors can vary from lot to lot, wafer to wafer, die to die, and within each die, especially for nanometer process technologies. The range of variations could be as large as 50% of the nominal value. In addition, the electrical characteristics of the NMOS and PMOS vary widely over the voltage and temperature range. Such wide variations in device characteristics in turn lead to large variations in the electrical characteristics of the analog circuit that are extremely difficult to control. Currently, there are no comprehensive methods to help designers create analog circuits that can have electrical characteristics immune to the wide range of process, voltage, and temperature.

The second challenge is that with the current analog design method, there is no approach to correct the analog circuit after tape-out if it fails to meet the specifications at an unpredicted PVT condition. The existing methods focus solely on designing and verifying analog circuits via simulation, where the circuit design changes must be done before tape-out. Currently there are no efficient methods and systems to design analog circuits that can work post-tapeout on silicon to internally change themselves on-the-fly to compensate for the spec deviations caused by unpredicted changes in PVT conditions.

Further, the third main problem with the conventional analog circuit design is managing the complexity of analog circuits. To meet specifications across a wide range of PVT conditions, designers must incorporate compensation and biasing circuits into the main circuit and use intricate circuit configurations for the analog circuits to meet specifications across a wide range of PVT conditions, especially at the extreme conditions where it is most difficult. This “design-for-worst-case” method leads to large in die area, high power and complexity, but still leaves widely varying electrical characteristics over the PVT range.

The fourth challenge facing the designers is to fully comprehend the intricate relationships between PVT conditions, device electrical parameters, and device configurations in the analog circuits, as well as various functions and design specifications. Deviations from the nominal specifications result from changes in the electrical characteristics of internal components that also interact with one another over PVT conditions in highly complex ways. Each component can have between 5 and over 100 parameters, and an analog circuit can consist of 10 to over 500 internal components. Additionally, an analog circuit can have 10 to 50 electrical specifications, all of which are influenced differently by the varying characteristics of internal components across the PVT range. To fully verify the functionality and specifications of the analog circuit across all possible PVT conditions, the designer must run over 1,000 simulations to exhaustively check every condition. However, the designer cannot practically review all simulation results and thoroughly analyze such a vast amount of data to understand the tremendously complex interactions among device parameters, actual device characteristics (e.g., size, gate length), electrical specifications, and PVT conditions. Consequently, it can be difficult to identify the few PVT conditions where the analog circuit may fail.

Another problem analog designers encounter is the lack of an efficient model to describe the behavior of the analog circuits under different PVT conditions. Such a model is created by distilling useful information from the large amount of simulation results. It efficiently captures and preserves such information to use for future evaluation, to predict failure points, and to correct them without the large effort and computer resources of running SPICE simulations. Circuit designers currently use schematic capture tools to build netlists, simulator software to run circuit simulation and analysis via test benches, etc. on commercial design platforms that are widely available and well understood by a large workforce of design circuit designers. With advanced nanometer process technologies, the SPICE models of the semiconductor devices or components in the full SPICE netlist of the analog circuit also become very complex, with up to 100 different parameters each. Therefore, for complex analog circuits, each SPICE run can take hours or days on powerful servers and the results can take several gigabytes of disk space. Currently, the simulation results are not efficiently stored. If simulation results are required for subsequent evaluation, failure analysis, or to define any changes for the analog circuits, the simulation results have to be recreated by rerunning the Spice simulations. This inefficient process wastes much time and computer resources.

The sixth challenge the circuit designers face is the creation and preservation of the design “knowledge base” for later use. With the current design method and system, such design “knowledge base” derived from the large number of SPICE simulations is not fully captured anywhere, mainly because there are no means to efficiently represent that large volume of information.

The seventh challenge for the designers is that changes to analog circuits are made today inefficiently through extensive simulation and verification using the circuit SPICE netlist. If a simulation result shows a failure, the designer must modify the circuit and re-run many simulations to confirm that the failure is resolved in all possible scenarios. This iterative process consumes significant time and computer resources, which can delay the development process and increase costs.

The eighth and final challenge is that the conventional analog circuit design method requires that all design and verification work be done before the circuit is realized on silicon. The current method requires that any post-silicon changes to the analog circuits must be done with mask changes, new silicon manufactured, and re-verification of the analog circuits on silicon. Such work could cost millions of dollars and take 3 to 6 months to complete.

The existing methods have attempted to correct the off-tune behavior of circuits over the ranges of PVT, but it has become widely adopted only for digital circuits through changes only to frequency and voltage externally applied. Many conventional digital ICs include some sort of process and voltage monitors that provide closed-loop feedback control useful to compensate for such off-tune behavior. The off-tune corrections are limited to modifying the operating clock frequency or changing the supply voltage of the digital circuits, or both. The well-known dynamic voltage frequency scaling or DVFS method for digital circuits uses voltage monitors that provide a closed-loop feedback control useful to optimize the power consumption for a particular performance target but is limited to modifying the operating clock frequency and the supply voltage from the outside of the ICs. Modifying the chip's operating frequency is done at the system level by changing the frequency of the clock signal feeding the chip or the frequency of the chip's internally generated clock signals. Similarly, the chip supply voltage is changed by varying the output voltage of an external voltage regulator feeding the chip. No changes to the internal components of the chip are done. DVFS is strictly limited to digital circuits, especially microprocessors or system-on-chip devices. DVFS does not work for analog circuits because of their different nature. Analog circuits are mostly non-repetitive and structured very differently from the digital circuits that are built as regular patterns of gates.

Conventional semiconductor microelectronic circuit design methods and systems have produced chips that can monitor and tune certain operational circuit behavior. IC chips that have controllable circuit parameters have been equipped with a process monitor that includes logic for evaluating the behavior of an operational circuit based on data obtained from a process monitor module and operational circuit-related data stored in a memory. However, that method using PVT sensors coupled with a controller and memory storing circuit data can only compensate for the imbalance caused by a few process parameters and a few components of the operational circuit. There was no mention of any way to represent or model the behavior of the analog circuit in the various PVT conditions.

Most importantly, the method of US 2008/0265929 A1 is an open loop compensation system. The open loop system relies on circuit data related to the components and the PVT conditions stored in memory. Due to the very large number of possible combinations, there is a high probability for some missing data points that could lead to inaccurate compensation or even circuit failures after compensation. Given the large number of device types, device parameters, and the much larger number of possible interactions between them in analog circuits over PVT, an open loop system of compensation must be limited in scope and PVT range, and the applicable analog circuits must be simple with few components to eliminate the risk of malfunction after compensation.

In view of the foregoing, there is a need for a universal, more capable, and less risky method to create analog circuits capable of changing themselves on-the-fly to compensate for the effects of varying PVT conditions. Further, there is a need for a method or design system that allows the circuit designer to efficiently distill simulation results into useful information, detect or predict potential failure points, and correct them. Moreover, there is a need for a compensation method that can simultaneously compensate for multiple interacting specifications and is universally applicable to all types of analog circuits.

The above-mentioned references are exemplary, and are not meant to be limiting with respect to the resources and/or technologies available to those skilled in the art. Of course, it should be realized that the hardware for implementing a system may be integrally related to the choice of a specific method or software algorithm for implementing the system, and therefore these together form a system. It is noted that in view of the present disclosure, it is within the skill of the artisan to combine in various fashions the available methods and systems to create self-adapting analog micro-electronic circuits of the present disclosure.

### SUMMARY

The embodiments herein disclose a method of creating a self-adapting analog micro-electronic circuit. The method comprises specifying an analog micro-electronic circuit with a set of specifications, creating, by a simulation test bench creator module, a simulation test bench applicable to the specific simulator based on an inputted simulation configuration and control directives, generating, by a database builder, a query database from simulation results that capture relationship between one or more of input conditions, output specification values, critical parameters of dominant components, process, voltage and temperature PVT over a complete range of PVT, generating, by a sensitivity analyzer, a plurality of Pearson coefficients relating the input changes to the output changes under various PVT conditions, creating, by a Machine Learning ML creator module, a Machine Learning ML model based on the plurality of input and output specification variables to represent responses of an analog circuit to changes in the P, V, and T parameters and creating a self-adapting analog circuit and by using the machine learning models to re-tune its output specification variables. Here re-tuning of the output specification variables comprises estimating using the ML model, values of the critical parameters of dominant components required to re-tune the specifications of the analog circuit to predetermined nominal values.

According to the embodiments herein, creating a self-adapting analog circuit configured to re-tune its specifications to predetermined nominal values comprises creating an original netlist for a base analog micro-electronic circuit conforming to the specifications, selecting one or more key parameters associated with the dominant components, designing a control circuit block co-located with the base analog micro-electronic circuit, designing a tuning circuit block co-located with the base analog micro-electronic circuit, assembling a full circuit comprising the base analog micro-electronic circuit, the control circuit block, and the tuning circuit block, creating a test bench of the full circuit, simulating the full circuit with the test bench, analyzing and formatting the full query database from simulation results obtained through simulating of the full circuit, creating a machine learning ML training database from the data analyzed and formatted in the previous step, creating and training the ML model, predicting results using the ML model and inputting associated control data to the control circuit, directing, by the control circuit, the tuning circuit to change the dominant components in a way to re-tune the specifications of the analog circuit to predetermined nominal values, verifying the functioning of the ML model, testing whether the function of the re-tuned circuit conforms to the specifications, and if not, repeating the steps of creating and training an ML model and releasing to layout for semiconductor fabrication the full circuit. The self-adapting analog circuit is configured to change its internal components on-the-fly in response to changes in process, voltage, and temperature parameters to re-tune its output specification values that have deviated back to the predetermined nominal values.

According to some embodiments herein, the method of creating an ML model further comprising selecting the ML model from an ML library of previously created and trained ML models according to one or more criteria including Llnorm, or L2norm, or r2 score and compute times, accessing the Cloud a data file of previously created ML training databases; or accessing and selecting the ML model from a library comprising pre-stored analog circuit, control block and adaption circuit designs.

According to some embodiments herein, the method of implementing a base analog circuit topology by drawing the analog circuit in a composure window, completing any biasing arrangements, checking for operating point margins, and aligning the design for preferred PVT conditions.

According to another embodiment herein, the method of generating, by the database builder, a query database from simulation results comprises of running simulations across PVT and capture data, distilling, and formatting the simulation data into the full query database representing the relationships between the inputs, the critical parameters of the dominant components, and the output specifications over all the simulated PVT conditions.

According to another embodiment herein, the method of generating the query database further comprises of using Pearson coefficients to describe correlations between the changes in the output specifications, the changes in PVT conditions and the changes in the critical parameters of the dominant components and deriving from the full query database a machine learning dataset containing only the data describing the correlations between the changes of the output specifications and the changes of the critical parameters of the dominant components over all the simulated PVT conditions.

According to another embodiment herein, the method further comprises creating an ML data domain representing each self-adapting analog circuit. The ML data domain comprises one or more of the ML models of the analog circuit, the full query database unique to the analog circuit distilled from simulation results, the ML training dataset for the analog circuit, the PVT sensor data as received from the sensors and the control data to re-tune the analog circuit for requisite PVT conditions.

According to another embodiment herein, the method further comprises changing design of analog circuits in the ML data domain through one or more of using sensor data to determine new PVT conditions encountered, using the ML model to predict the specifications under the new PVT conditions, calculating differences between the specifications under the new PVT conditions and the specifications under nominal conditions, using the ML model to estimate the values of the critical parameters of the dominant components required to re-tune the specifications back to their values under nominal conditions, determining the control data required to change the dominant components such that the specifications of the analog circuit under the new PVT conditions are changed back to their values under nominal conditions, and providing the control data to the tuning circuit to re-tune the analog circuit.

According to another embodiment herein, the method further comprises updating the ML model of the self-adapting analog circuit before tapeout or on silicon. The method comprising one of changing a self-adaptation method, formulae, or equations, changing a level of accuracy of any self-adapted specifications, expanding, or reducing a range of PVT conditions for self-adaptation, adding input variables or output specifications for self-adapting or changing emphasis on a set of specifications over other specifications for self-adapting.

According to some embodiments herein, the method of creating the self-adapting analog circuit further comprising at least one of creating a self-adapting analog circuit comprising several smaller circuits and using a single top-level machine learning model to re-tune a single specification or multiple specifications.

According to some embodiments herein, creating a self-adapting analog circuit comprising several smaller circuits comprises creating a self-adapting analog circuit comprising several smaller circuits connected in a hierarchical manner by at least one of using hierarchical machine learning models comprising a top-level wrapper integrating the machine learning models of those smaller circuits according to certain priority or emphasis rules, adjusting the top-level hierarchical machine learning model using hyper-parameter tuning for accuracy and using the hierarchical machine learning model to re-tune a single specification or multiple specifications.

Embodiments herein further disclose a computer system for creating self-adapting analog circuits comprising a local workstation for user interface connected to a local disk containing local design data, a network cloud connecting the local workstation with a tool license server, and a main compute server, a main compute server running all complex tasks of simulation, Machine Learning ML model creation, training, and verification, a main storage disk connected to the main server containing all design data including final netlist, simulation results, full query database, final ML model, sensor library, PMON library, circuit libraries, and reports and log files. The computer system comprising a design entry and interface module residing in the local workstation to specify an analog micro-electronic circuit with a set of specifications, a simulation test bench creator unit to create a simulation test bench applicable to the specific simulator based on an inputted simulation configuration and control directives, a database builder to generate a full query database from simulation results that capture relationship between one or more of input conditions, output specification values, critical parameters of dominant components, process, voltage and temperature PVT over a complete range of PVT, a sensitivity analyzer to generate a plurality of Pearson coefficients relating the input changes to the output changes under various PVT conditions, a Machine Learning ML creator module to create a Machine Learning ML model based on the plurality of input and output specification variables to represent responses of an analog circuit to changes in the P,

V, and T parameters; and a self-adapted circuit netlist output module to create a self-adapting analog circuit by using the machine learning models to re-tune the output specification variables. Here retuning the output specification variables comprises estimating using the ML model, values of the critical parameters of dominant components required to re-tune the specifications of the analog circuit to predetermined nominal values.

According to some embodiments herein, a combination of several or all of the following modules is stored in its memory and called upon to build ML models for self-adapting analog circuits. The computer system further comprises of: a design entry and interface module to interface to the user and other design tools, a simulator module to interface to an analog circuit simulator, a dominant component checker unit to verify if dominant components picked by the user are valid or not, a simulation test bench creator unit to create one or more test benches specified by the user for the analog circuit under test, a query database builder to build full query database from simulation results to build the machine learning models, a sensitivity analyzer unit to analyze the simulation results and formulate relationship between a plurality of critical parameters of the dominant components and the circuit specifications over pressure, voltage, temperature PVT parameters, a Machine Learning ML model creator to create one or more ML models of the analog circuits according to one or more user-defined criteria's, a Machine Learning ML training dataset builder to build training data and test data subsets for the ML models, a Machine Learning ML model trainer to train the created ML models, a Machine Learning ML model checker to check the accuracy of the ML models and a Machine Learning ML log and report generator to create and display log and report files per user instruction.

According to some embodiments herein, the computer system further comprises a combination of several or all of the following modules stored in its memory and called upon to build ML models for self-adapting analog circuits. The computer system further comprises of a configuration parser module to parse a configuration file in text format to separate and store the user inputs, system commands, simulation configurations, and output instructions related to the analog circuit being designed, a netlist parser module to parse the netlist of the analog circuit text format to extract the information and instructions for simulation, a simulator interface module to send and receive data and commands from the simulator, a simulation measurement and calculation module to formulate the relationships between the inputs and outputs, a ML model creation module to create an optimal ML model according to pre-set user-defined criteria's, a ML prediction module to predict from the ML model output values according to an input type, a test bench recreation module to create updated test benches for the self-adapting analog circuit updated with changes recommended through control data, a design specific verifier to verify from simulation results that the self-adapted analog circuits according to the created control data to meet the required specifications and a self-adapted circuit netlist output module to generate a final netlist of the verified self-adapted analog circuit and the log files.

The embodiments of the present disclosure enable the analog circuit designers to capture all the multitude of component interactions in the forms of query databases, machine learning datasets, and machine learning models, and use them to accurately and confidently predict the behavior of the analog circuit under various PVT conditions, and derive changes for risk-free, successful and accurate re-tuning or self-adapting. The method and system disclosed herein use machine learning to create all types of analog circuits that can re-tune or self-adapt by themselves to negate the detrimental effects of the changes in PVT conditions, especially at the extreme corners of the specified PVT ranges. These self-adapting analog circuits work robustly across the PVT ranges because their electrical characteristics are automatically brought back through the self-adapting process to be close to their values at the nominal PVT condition. Hence the range of variation of the electrical specifications of the analog circuit will be much smaller, resulting in better overall performance.

Additionally, the method and system of the present disclosure, enables the circuit designers to capture all the learning derived from thousands of simulations in query databases, machine learning datasets and machine learning models, and subsequently utilize them to efficiently, accurately and confidently predict the behavior of the analog circuit under any PVT conditions without having to revert to SPICE simulations to validate its behavior change. The machine learning model can be a polynomial model or an ensembled-regression model, both being compact and easily transportable. Predicting any circuit behavior change using machine learning model demands much less compute resources, up to 100,000 times less, and can give results in seconds compared to the minutes, hours, or days for SPICE simulation and for the circuit designer to analyze the results.

According to the embodiments of the present disclosure, the circuit designer creates for each analog circuit a new type of model, a machine learning model or ML-model that can capture the design “knowledge base” of the circuit in a transportable and efficient format that can be changed, adjusted, and augmented over time. The ML-model is used to predict the behavior of the analog circuit efficiently, accurately and confidently under any new

PVT conditions to validate its behavior change. Evaluation of the adverse effects of PVT changes, decision on required circuit changes, and realization of the circuit changes are now done automatically in the “machine-learning data domain” in seconds and with several orders of magnitude less computer resource. Such a task is efficient enough that it can be done with a micro-computer co-located with the analog circuit on silicon or placed elsewhere.

Furthermore, the ML model can be created by the designer in the design phase with enough margins and features so that it can be updated after deployment of analog IC to perform one or more of the following:
Change the self-adaptation method, or formula, or equation,
Change the level of accuracy,
Expand or contract the range of PVT conditions,
Add input variables or output specifications for self-adapting,
Change the emphasis on certain specifications for self-adapting, etc.

Any of the above changes would tune the analog circuit differently resulting in modified output specifications, all without hardware changes. This type of change is not possible with the conventional analog circuits.

The method and system based on machine-learning in the present disclosure allows the circuit designer to efficiently distill the thousands of SPICE simulation results into efficient machine learning models, use them to confidently predict the behavior of the analog circuits before and after tape out, and decide whether the changes would work in all required PVT conditions. Using machine learning models, the circuit designer can create self-adapting analog circuits that change their internal components on-the-fly during the design phase or on silicon in response to changes in process, voltage, and temperature to re-tune or self-adapt their electrical characteristics back to nominal specified values. Such changes are already verified to be safe with machine learning models. According to the embodiments herein, the changes to the analog circuit to be made pre- and post-tape out, on-the-fly during the design phase or on-the-fly on silicon with no simulations, very little computer resources and very short time.

According to the present disclosure, the method and system herein allows design of such self-tuning or self-adapting analog circuits that will never fail the specifications. The self-adapting analog circuits can be implemented on silicon as integrated circuits or assembled using discrete components mounted on printed circuit boards. Further, the self-adapting analog circuits to be designed according to the embodiments herein, consume less power and take smaller die area. Because they can change their internal components in response to unpredicted PVT conditions, they usually do not need to have complex configurations or add-on circuits.

The embodiments of the present disclosure further enable the circuit designer to select a priori and prioritize the parameters in the specifications that will be “tuned” while keeping the others within the required spec boundaries.

The embodiments of the present disclosure are based on machine-learning which will help the circuit designer to build a comprehensive design “knowledge base” in the form of query databases, machine learning datasets and machine learning models that will eliminate the inefficient and iterative change process, rapidly predict and reliably remedy any potential failures.

These and other aspects of the embodiments herein will be better appreciated and understood when considered in conjunction with the following description and the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF THE DRAWINGS

The embodiments herein will be better understood from the following detailed description with reference to the drawings, in which:

FIG. 1A illustrates specifications of a sample current reference implemented on a 40 nm process, for a supply voltage of 0.8V+/−10% and temperature between −55° C. and 125° C., according to prior art;

FIG. 1B is a schematic representation of an analog circuit of the current reference in FIG. 1A, according to a prior art illustration;

FIG. 2 is a flow diagram representing a conventional analog circuit design method that includes the inefficient design change loop, according to a prior art illustration;

FIG. 3 is a flow chart of a method to Create and Train a Single-Output ML Model for a Self-adapting Analog Circuit, according to prior art illustration;

FIG. 4 is a flow chart illustrating a variable pruning method for the ML Model of a self-adapting Analog Circuit, according to according to prior art illustration;

FIG. 5 is a flow chart illustrating a method to create and train a hierarchical multi-output ML model for a self-adapting analog macro circuit, according to prior art illustration;

FIG. 6 represents a table showing prediction accuracy of ML model, according to prior art illustration;

FIG. 7 is a tabular representation of resistor tuning trim code generated from ML model for different PVT conditions, according to prior art illustration;

FIG. 8 is a schematic representation of a complete self-adapting current reference with base current reference, tuning and control circuits, according to prior art illustration;

FIG. 9 represents Specifications of current reference with self-adapting analog circuits, according to prior art illustration;

FIGS. 10A-10B are flow diagram illustrating a design method to self-adapt a single output of an analog circuit, according to embodiments herein;

FIG. 11 is a diagram representing two ways to represent and manipulate the design-related data in the Circuit Domain and the ML Data Domain, according to embodiments herein;

FIG. 12 is a flow diagram that illustrates comparing of methods for making analog circuit design changes in the Circuit Design Domain and ML Data Domain; according to embodiments herein;

FIG. 13 is a block diagram illustrating a Computer System for the design of self-adapting analog circuits SAC design system, according to embodiments herein;

FIG. 14 is a block diagram illustrating modules in self-adapting analog circuits SAC Design System to create the ML Model for self-adapting analog circuits, according to embodiments herein;

FIG. 15 is a flow diagram illustrating interaction between modules of the SAC Design System to create the ML model for a self-adapting analog custom circuit, according to embodiments herein;

FIG. 16 is a flow diagram illustrating interaction between modules of SAC Design System to create the hierarchical ML Model for a self-adapting analog macro circuit with several sub-blocks from a circuit library, according to embodiments herein;

FIG. 17 is a flow diagram illustrating ML data generation and data flow of SAC Design System to create the ML Model of a self-adapting analog macro circuit, according to embodiments herein;

FIG. 18 represents SAC-based design flow to create the ML model of a self-adapting analog circuit, according to embodiments herein;

FIG. 19A is a block diagram illustrating various modules of an embodiment of the SAC Design System for self-adapting analog circuits, according to embodiments herein;

FIG. 19B is a flow diagram of a front-end design method for self-adapting analog circuits, according to embodiments herein;

FIG. 20 is a flow diagram illustrating various Modules of an implementation of the SAC Design System for self-adapting analog circuits, according to embodiments herein;

FIG. 21A is a schematic representation of samples setup and configuration files of SAC Design System, according to embodiments herein;

FIG. 21B is a screenshot of the Graphical User Interface GUI of SAC Design System, according to an exemplary illustration of the embodiments herein;

FIG. 22 represents of configuration control file of SAC Design System; according to an exemplary illustration of the embodiments herein;

FIG. 23 represents corners and measure control files of SAC Design System, according to an exemplary illustration of the embodiments herein;

FIG. 24 is a screenshot of GUI showing results of ML Modeling from SAC Design System, according to an exemplary illustration of the embodiments herein;

FIG. 25 represents details of ML Model training results, according to the embodiments herein;

FIG. 26 represents log file showing training process and results of ML model, according to the embodiments herein; and

FIG. 27 is a flow chart illustrating a method of creating a self-adapting analog micro-electronic circuit, according to the embodiments herein.

### DETAILED DESCRIPTION OF PREFERRED EMBODIMENTS

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

Embodiments of the present disclosure includes using machine learning models to create self-adapting analog circuits that change their internal components on-the-fly in response to unpredicted changes in process, voltage, and temperature to bring their electrical characteristics that have shifted away back to nominal specified values.

According to the embodiments herein, the method comprises building a complete query database from the simulation results that capture all the relationships between the input conditions, the output specification values, the critical parameters of the dominant components, the process, the voltage and the temperature over the complete range of PVT. The method further comprises building a machine learning ML model with data from the full query database to represent the responses of an analog circuit to changes in the P, V, and T conditions on its operation. The full query database is distilled from simulation results using data collecting and analysis methods.

In each analog circuit, there are several internal components that have much stronger influence on the electrical specifications of the analog circuit than the other component, termed as “dominant components”. When their electrical characteristics change with the process, voltage, and temperature, such changes dominate over the changes of the other components. More specifically, a certain number of the electrical characteristics or “parameters” of the dominant components are much more influential than the others, termed as “critical parameters”. As a result, the changes caused by PVT in the critical parameters of the dominant components have much stronger correlation with the changes in the electrical characteristics of the analog circuit. Sensitivity analyses are performed on the collected data to find the “critical parameters” of the “dominant components” using statistical data analysis tools.

The machine learning model herein is coded and used by a processor or computer to first infer the changes in the output specifications caused by the changes in PVT conditions. Comparing the new values to those at the nominal PVT condition, the processor derives the changes needed for one or more of the dominant components, e.g., sizes, values, connections, etc. to bring the electrical characteristics of the analog circuit that have shifted away with changes in PVT conditions back to their nominal specified values. Given there are many possible ways to change the dominant components to achieve the same results, the processor uses the machine learning model to select the best solution. The processor uses the machine learning model to estimate the new values of the output specifications as if the changes were implemented and verify that they are indeed close enough to the nominal values. If they are not, another solution is picked. The process is repeated until the best solution is found. Finally, the processor generates the corresponding change control commands to effectuate the changes of the dominant components in the analog circuit. It can thus be inferred from the above discussion that the design method using an accurate machine learning model always yields accurate results and SPICE simulations are no longer required.

Further, analog circuit designers can employ the method and system described in the present disclosure to design self-adapting analog circuits at the factory. Analog circuits designed with this method are implemented on silicon with co-located supporting hardware like process monitors, voltage and temperature sensors to monitor the environmental conditions, a co-located processor for calculations, computer memory to store the machine learning model, and control circuits to effectuate the change control commands inferred by the processor using the machine learning models of the analog circuits.

Other embodiments of analog circuits can be created with discrete components with co-located supporting hardware like process monitors, voltage and temperature sensors, a co-located processor or microcomputer for calculations, computer memory to store the machine learning model, and control circuits to effectuate the change control commands inferred using the machine learning model.

For efficiency, the machine learning model implemented in this disclosure uses Pearson coefficients to represent the correlations between the changes in the performance characteristics of the analog circuit, the changes in the PVT conditions, and the changes in the “critical parameters” of the “dominant components”.

To ensure the accuracy of the machine learning model, a large amount of learning data is used for training. The simulation results by analog simulators like SPICE running on fast computers are distilled into a full query database from which the machine learning dataset is generated. Subsequently, the machine model is created and then trained using the same computers. Once the query database, dataset, and the machine leaning model are created, they can be re-used, expanded, or changed. The model is then used to infer changes to one or more of the dominant components to respond on-the-fly to the variations of PVT in order to revert the performance characteristics of the analog circuit back to their nominal values.

Traditionally, any changes in the analog circuit must be decided by the designers in the design stage before the circuit is fabricated and must be verified with extensive SPICE simulations that run on powerful computers for significant lengths of time, many times for hours, all for fear of failure. Using the design method with machine learning model described in this disclosure, internal changes in the fabricated analog circuit in response to changes in the PVT conditions are computed and decided on-the-fly using very little computer resource and time, typically in several seconds for small circuits. New SPICE simulations are no longer needed.

Analog circuits created from the method according to the present disclosure can be changed or directed to change themselves periodically or on-demand according to the PVT conditions encountered to negate their effects on their electrical characteristics. All the self-adapting changes can be done before and after the silicon is made. Due to the self-adaptation, tighter specifications can be achieved for analog circuits over wider PVT conditions compared to circuits created from conventional methods. Thus, the overall performance of the analog circuits and systems using them is increased.

According to the embodiments herein, the machine learning ML model and a co-located processor are used to control analog circuits that adapt themselves to PVT conditions to negate their adverse effects on the analog circuit characteristics so as they adhere to a very tight set of specifications over the wide range of loading and PVT conditions. The same design method can be expanded to all types of complex functions memories, graphic units, processor cores, etc., sub-systems graphics boards, FPGA boards, etc., system on chip SOC devices, microcomputer μCs, computers, networking equipment, etc. The self-adapting analog circuits can be implemented on silicon as integrated circuits or assembled using discrete components mounted on printed circuit boards.

The method of creating self-adapting analog circuits in this disclosure is realized by a design system including all the tools, modules and data files to perform tasks such as controlling the simulation tools, managing the design data, generating, and training the ML model of the analog circuit, and creating the required control register and the tuning circuit. The design system can be used to create self-adapting analog circuits to be implemented on silicon as integrated circuits or assembled using discrete components mounted on printed circuit boards.

The design system includes at least the user interface, simulator interface, simulation control, design, and database control modules necessary to perform such creation. An embodiment of such a system running on a computer comprises first of a graphical user interface or GUI. The system also includes an application interface to industry-standard analog circuit simulators like Cadence's Spectre or Mentor Graphics' HSpice to exchange information such as circuit netlists, simulation control commands, and simulation results. Modules such as Simulation Test Bench Creator, Input Sensitivity Analyzer, Training Data Generator, and Analyzer are used by the ML Model Creator module to generate the machine learning model which is then trained through the ML Model Trainer module and verified accurate by the ML Model Checker module. Associated databases are a) Simulation Data to store simulation results; b) Training Data to store the complete set of training data created from simulation results; and c) Circuit Data containing all the design data of the circuit, including the newly created ML model. Variations of such systems can be created according to the user's needs.

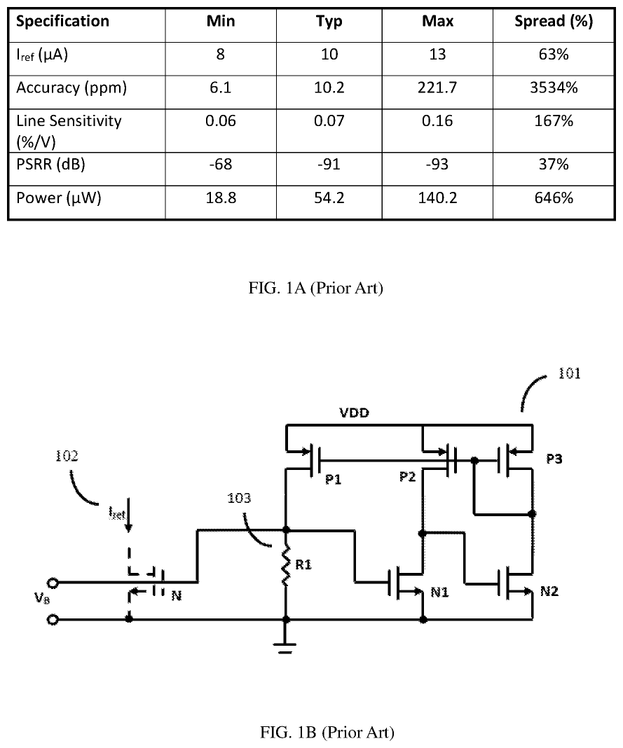

Referring now to the drawings, and more particularly to FIGS. 1 through 27, where similar reference characters denote corresponding features consistently throughout the figures, there are shown preferred embodiments.

FIG. 1A illustrates specifications of a sample current reference implemented on a 40 nm process, for a supply voltage of 0.8V+/−10% and temperature between −55° C. and 125° C., according to prior arts. FIG. 1B is a schematic representation of an analog circuit of the current reference in FIG. 1A, according to a prior art illustration.

FIG. 1A shows the electrical specifications of the current reference, a commonly used analog circuit, designed on a 40 nm process technology, and FIG. 1B shows its schematic 101. The single output which is the current reference I_{ref} 102 has its value and other four specifications spread widely over the PVT range, even though the analog circuit designer has done their best to optimize the design.

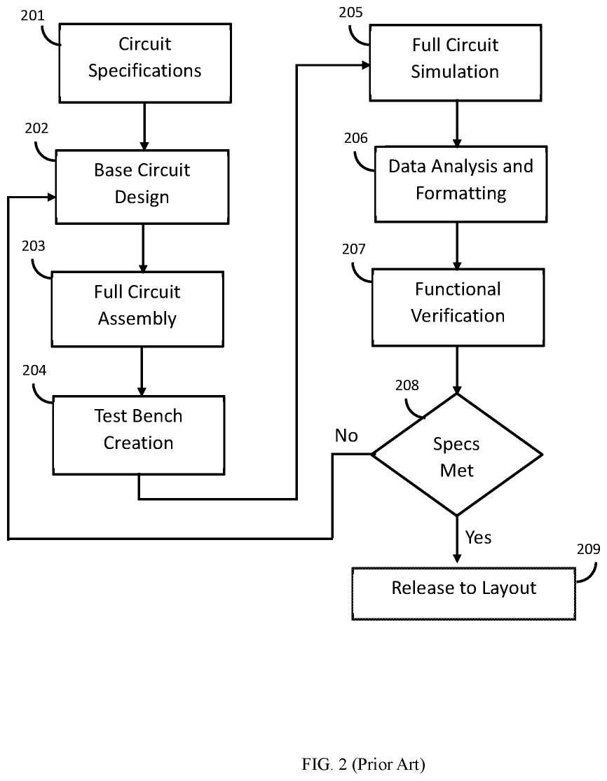

FIG. 2 is a flow diagram representing a conventional analog circuit design method that includes the inefficient design change loop, according to a prior art illustration. The conventional analog circuit design method is based on an iterative, design, simulate, verify, and design, process applied to continuously improve the design until a final version meets the required specifications is achieved and can be released to layout. The designer starts from the analog circuit specifications 201 to create the base circuit 202 which is the desired analog circuit function. Further, the sources of stimuli, supplies, simulated loading, noise sources, and the like are added which results in a full circuit assembly 203. The test bench 204 is the set of simulation command files that define the stimuli, the analyses, the conditions, and the outputs of the simulation that are of interest to the designer. However, these steps in the current methodology require significant design skill, knowledge, and experience. Here is when the circuit designer must meet the first challenge which is to an analog circuit design that meets its specifications over a wide range of process, voltage, and temperature limits.

Full circuit simulation 206 consists of running the hundreds or thousands of simulations specified in the test bench 204 using analog simulators such as SPICE, HSpice, PSpice, Spectre, Aldo, etc. As mentioned in a previous example, the possible number of PVT conditions for an industry-standard 22FDSOI process that circuit designers must look at above 200. Therefore, the number of simulations that would be required to check every of the 200 possible PVT conditions can be 1,000 or more depending on the circuit complexity. These simulations generate a huge amount of data and consume vast computer resources. This data is then formatted for reference and analysis 206. Currently, data formatting is done either manually or with some custom scripts using PERL, Python, or other computer languages. Analysis of the simulation results is also done either manually by the circuit designer or with the help of custom scripts. The circuit designer usually scans through the simulation results but focusses mostly on the worst-case PVT conditions, assuming that if the design meets the specifications at those conditions, it will at all others.

The results of data analysis 206 are keys to the functional verification step 207 which is to ascertain that the analog circuit is functional as intended and meets the specifications 208. If it does, the circuit design schematic is sent to the layout. If it does not meet the specs, the long loop back begins, where the circuit designer now must modify the base analog circuit 202. Depending on the situation, this loop back could involve hundreds of simulations, and take multiple iterations. In any case, it consumes lots of time and resources and can be unpredictable. Such iterations are known as big bottlenecks for analog design.

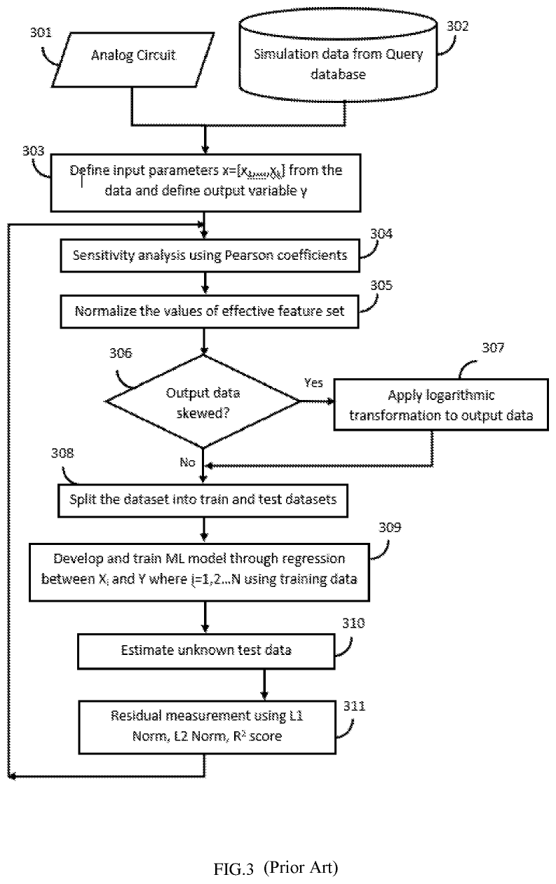

FIG. 3 is a flow chart of a method to Create and Train a Single-Output ML Model for a Self-adapting Analog Circuit, according to prior art illustration. FIG. 3 depicts the creation, training, and testing process of single-output machine learning model of a simple analog circuit such as the one shown in FIG. 1B. It should be noted that the same method can be applied to analog circuits with multiple outputs and specifications. Starting from the analog circuit 301 and the simulation data 302 stored in the full query database, the input parameters X=[x₁, . . . , xₖ] and the output variable y are defined in step 303 for the machine learning model. In the case of multiple outputs and output specifications, replace variable y with vector Y=[y₁, . . . , yₙ]. For the example of the current reference in FIG. 1B, it has been decided that the dominant component is resistor R1 and the critical parameter is its value over PVT conditions. The remaining input variables for the ML model are the process P, supply voltage V, and the temperature T. The output variable y in this case is the value of the current reference I_{ref}. A sensitivity analysis is then performed using the Pearson Coefficient method 604 correlating the changes of the output variable y to the changes of the input parameters [x₁, xₖ]. The inputs with Pearson coefficients below a certain minimum value will be removed to simplify the machine learning models. The focus on the changes rather than the actual values of the input and output variables also allows us to create simple yet accurate machine-learning models of the analog circuit. Such simplicity reduces computation resource and time when the ML models are used. The feature set is then formulated from the sensitivity analysis results then their values are normalized in step 305 to prevent accuracy degradation in subsequent calculation steps. Next, the output data is evaluated to detect any kind of skew step 306. If the skew is detected, a logarithmic transformation is applied 307 to reduce any extreme sensitivity so that the prediction from the ML model can converge faster to a solution. Next, the simulation data is divided into training data used to train the ML model and testing data used to verify the accuracy of the model 308. For example, 90% of the data may be reserved for training and 10% for testing. Training of the ML model can be done by one of the many available regression methods such as Multiple Polynomial Regression, Gradient Boosting, etc. In some embodiments, the machine learning model can be a polynomial model trained with a Gradient Descend method, or as an ensembled-regression model trained with either a Light Gradient Boosting Machine LGBM method, or an Extreme Gradient Boosting XGB method. The ML model may consist of several equations or neural network nodes describing the relationships between the input and output variables.

The relationships are mathematically represented by the coefficients of the equations or neural network nodes. The training process 309 is complete when all the coefficients are defined, and the equations or nodes accurately represent the relationships between the input and output variables. In some embodiments, the training process utilizes 90% of the simulation data to run through the regression process to calculate the coefficients of the equations. Once the training is complete, the model is capable of inferencing or predicting the outputs of any set of inputs. To test the trained ML model 310, its predicted output for one of the 10% test cases is compared to that obtained from the simulation results stored in the full query database. If the error or residual is below a certain threshold represented by Llnorm, L2norm and R2 score in step 311, the ML model is deemed accurate for that set of inputs of the test case. If the error is large 311, the machine learning model may be refined. The process is repeated for all the test cases pulled from the test dataset.

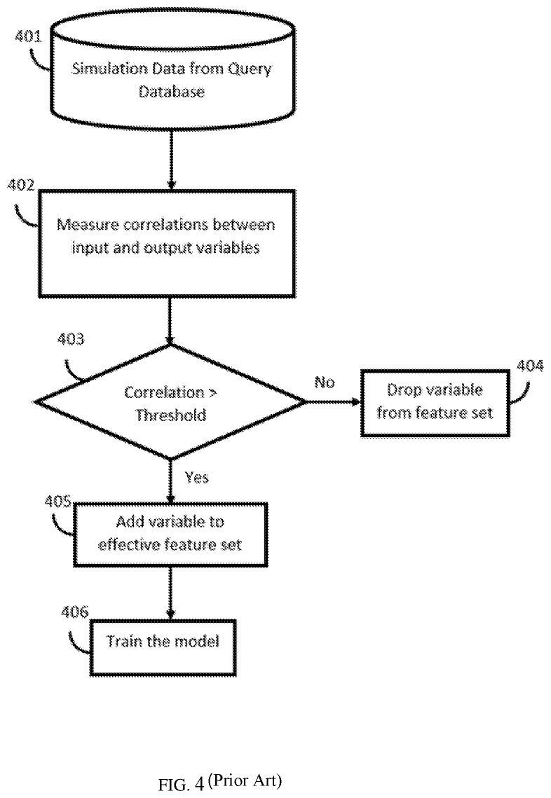

FIG. 4 is a flow chart illustrating a variable pruning method for the ML Model of a self-adapting Analog Circuit, according to prior art illustration. FIG. 4 details the method of pruning unnecessary variables in the process of creating the machine learning model of self-adapting analog circuits. Starting with simulation data stored in the full query database 401, sensitivity analysis is performed using the Pearson Coefficient method correlating the changes of the output variable y to the changes of the input parameters [x1, . . . , xk]. The resulting Pearson coefficients are measures of the correlations between the input and output variables. In step 403 the correlation coefficients are compared to a defined threshold. Variables that have higher correlation factors are added to the effective feature set 405 and those with lower correlation factors are dropped 404. The resulting effective feature set that includes only the variables that have the desired level of impact on the output is then used to train the machine learning model 406. It should be noted that adding or subtracting variables amounts to expanding or reducing the self-adapting coverage with an updated machine learning model. By using different correlation threshold values for different variables, the designer can effectively emphasize or de-emphasize any input variables for self-adapting. For example, a lower correlation threshold for voltage compared to those of other variables means that there are very few cases where voltage is considered in the self-adapting process.

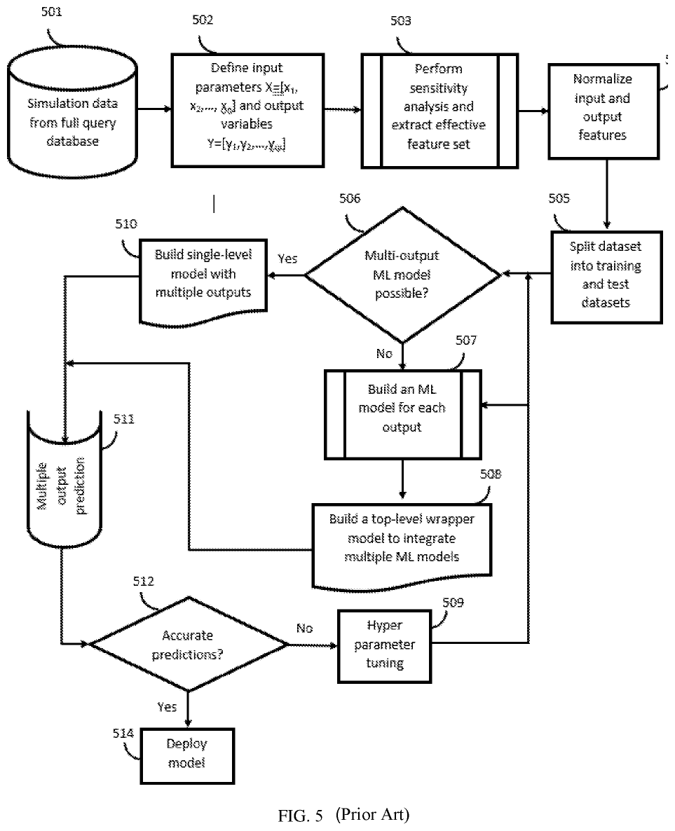

FIG. 5 is a flow chart illustrating a method to create and train a hierarchical multi-output ML model for a self-adapting analog macro circuit with multiple outputs and specifications, according to prior art illustration. The process starts with simulation data stored in the full query database 801. All the input parameters as in X=[x1, . . . , xn] and output variables Y=[y₁, . . . , yₘ] are defined 502 before sensitivity analysis via Pearson coefficients and feature set extraction are performed 503. The resulting input and output features are again normalized to prevent accuracy degradation in subsequent calculation steps. The dataset resulting from the effective features is then split into training and test subsets 505. A multi-output machine learning model is then created and evaluated through regression analyses 506. If the regression converges, the single-level multi-output model is the created 510. If there are difficulties in converging, the hierarchical method kicks in whereas a separate machine learning model is created for each of the outputs 507. The hierarchical method is more flexible as it allows changes to be made to the lower-level ML models without disturbing the top-level model and vice versa. Next, a top-level wrapper model is created 808 to integrate the multiple ML models. The top-level model is then used to predict the multiple desired outputs 511. If the desired accuracy is not achieved for any of the outputs 812, hyper parameter tuning is applied 509. Hyper parameter tuning can be applied to one or more of the individual ML models or to the top-level model. The training process using the training and test datasets will loop from 505 to 512 until the final model achieves the targeted accuracy 514.

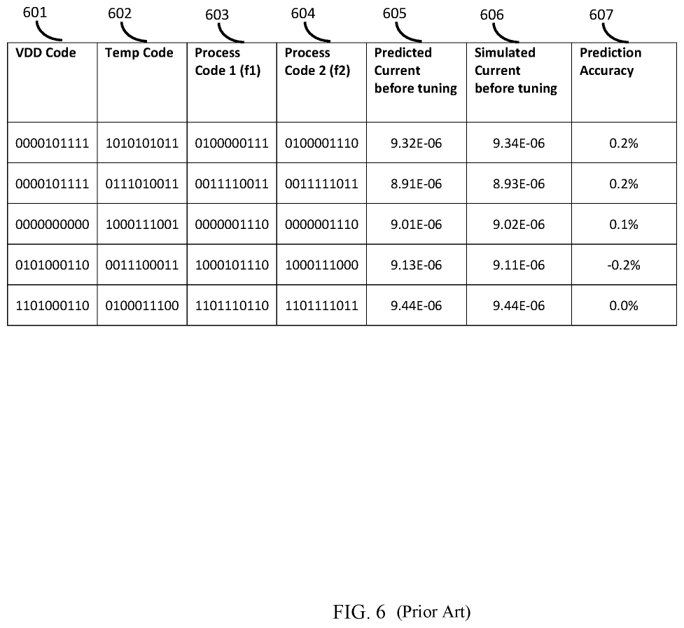

FIG. 6 represents a table showing the prediction accuracy of ML model, according to the embodiments herein. The left four columns 601-604 of the table represent the codes for voltage, temperature, and process. The predicted current for each PVT condition in 605 is compared to the simulated value 606. The prediction accuracy shown in 607 is excellent, at 0.2% or less.

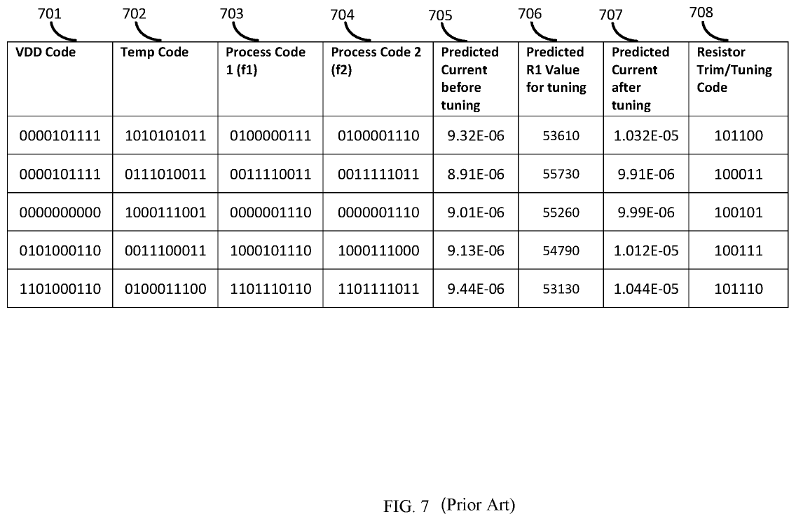

FIG. 7 is a tabular representation of resistor tuning (trim) code generated from ML model for different PVT conditions, according to the embodiments herein. The table of FIG. 7 shows the resistor tuning codes generated by the ML model 708. The design system predicts the value of the resistor needed at each PVT condition 706 to tune the current then predicts the resulting current value after tuning 707 to check for accuracy.

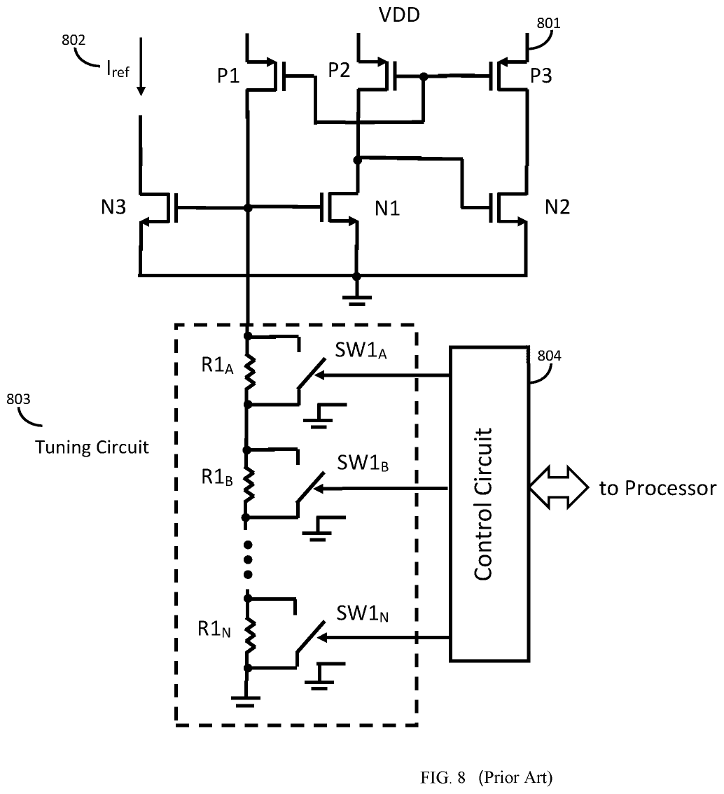

FIG. 8 is a schematic representation of a complete self-adapting current reference with base current reference, tuning, and control circuits, according to embodiments herein. The analog circuit design of FIG. 8 comprises a base current reference circuit 801, the current reference I_{ref} 802, the tuning circuit 803, and the control circuit 804. To enable more or fewer resistor sections, one or more switches SW1A, SW1B, are turned on by the control circuit 804.

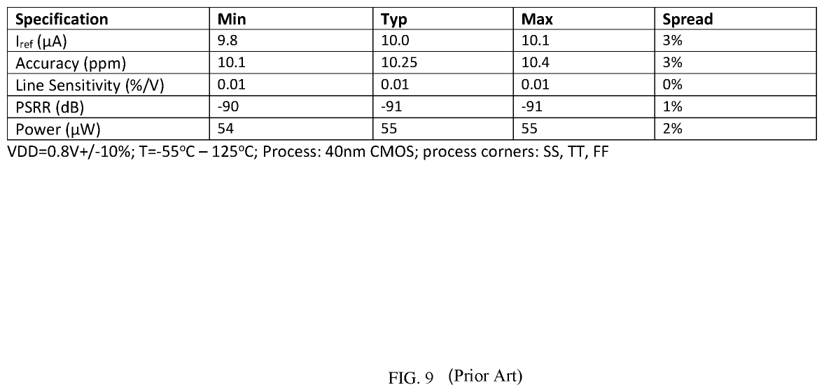

FIG. 9 represents Specifications of current reference with self-adapting analog circuits, according to the embodiments herein. All the specifications based on using the self-adapting analog circuit designs have a much lower spread over the wide range of PVT conditions as compared to those of the un-tuned circuit in FIG. 1B.

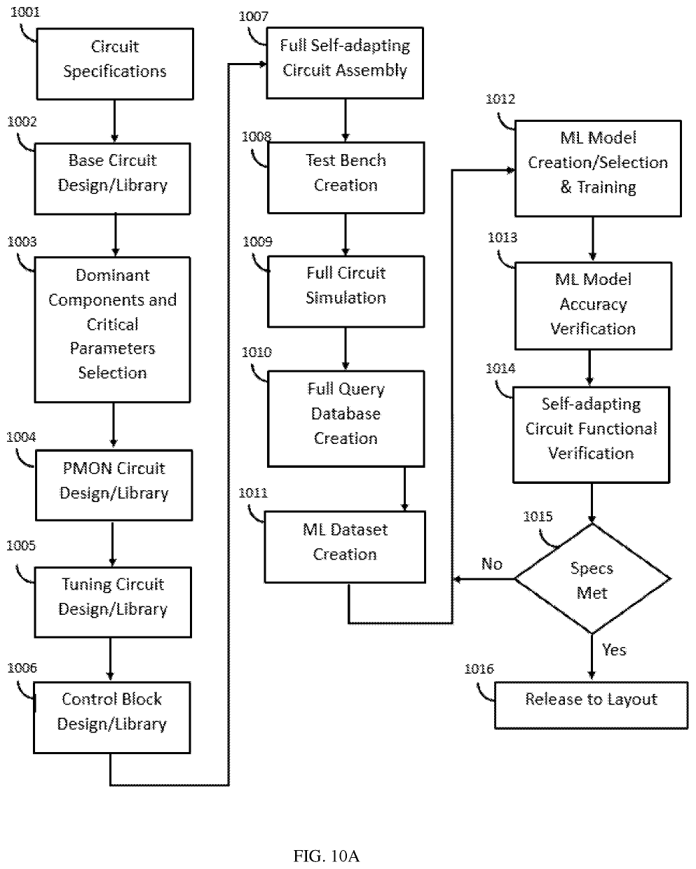

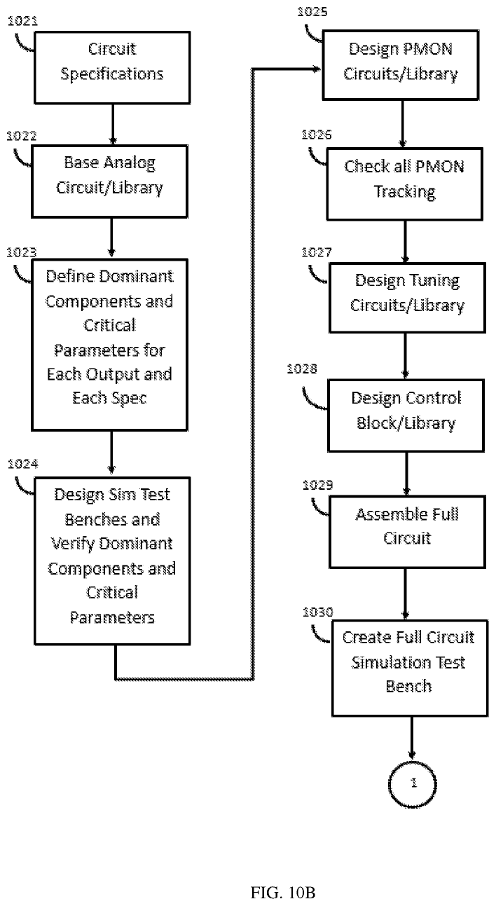

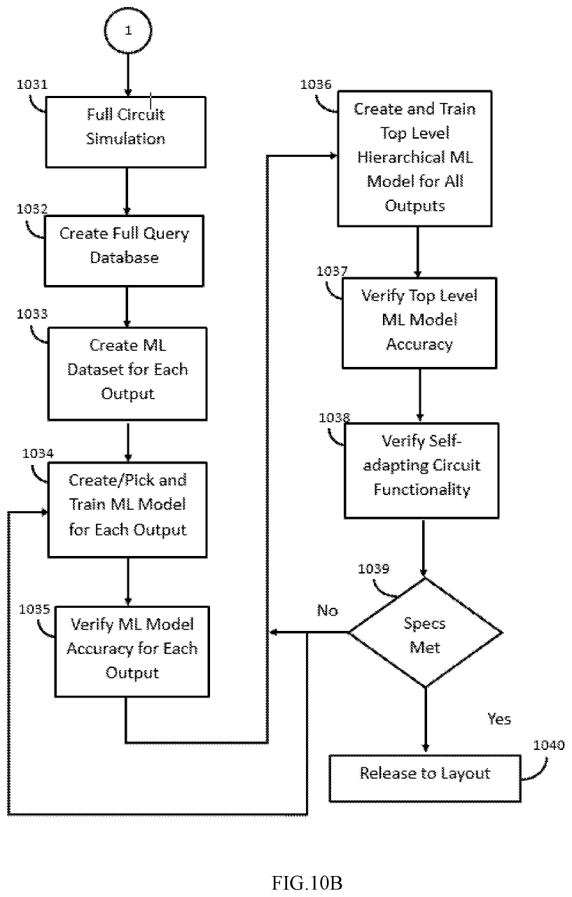

FIG. 10A is a flow diagram illustrating a design method to self-adapt a single output of an analog circuit, according to prior arts. One such circuit is the current reference 101 shown in FIG. 1B where the only output specification to be tuned is the reference current I_{ref} 102. The designer starts from the Circuit Specifications 1001 and creates the base circuit design 1002 such as the one shown in FIG. 1B. He will create simulation controls and run a limited number of simulations locally to verify that his design functions and meets all the specifications at the nominal PVT conditions. He would also verify his design is functional at the extreme PVT conditions, but it might not meet all the specifications. Achieving the above would make the next steps much easier and reduce the potential for rework.

The designer then decides, based on his knowledge and experience, the dominant components and their critical parameters 1003. The designer can also apply standard statistical techniques like Principal Component Analysis (PCA) or autoencoder to find the dominant components and their critical parameters. In the case of the current reference 101, the critical parameter is the value of the dominant component R1 103. There are several NMOS and PMOS transistors in the circuit whose electrical parameters vary significantly with PVT, but none of them has the same dominant role as the value of R1 in determining the final value of I_{ref}. Based on the selected critical parameters, the circuit designer designs the appropriate Process Monitor circuits PMON 1004 whose variations over PVT correlate with those of the critical parameters, in this case, the value of resistor R1. For example, he can use for PMON a ring oscillator with a series resistor between inverting stages which is a type of process monitor well known to those skilled in the art.

For each critical parameter and dominant component, the circuit designer then decides on the design of the tuning circuit 1005, the way it will be connected to the appropriate dominant component, and how it will change the value of the critical parameter in order to tune the analog circuit against PVT variations. This again is where the skill and experience of the design circuit designer are needed. He must also decide at this point the range and granularity of the tuning process conducted with the tuning circuit. The control block 1006 is designed according to the chosen range and granularity of the tuning circuit. The circuit interfacing the control block with the rest of the system is also decided at this step. Alternatively, the base analog 1002, PMON 1004, tuning 1005, and control block 1006 circuits as well as the ML models 1012 can all be picked from existing libraries to use as-is or with modifications to fit the current needs.

The base circuit, the tuning circuit, and the control block are then connected to form the full self-adapting circuit 1007. The test bench 1008 is the set of simulation tests with all the appropriate stimuli, analyses, and outputs that the circuit designer will then create based on the desired PVT ranges, the inputs, and the output under analysis. Simulations are run 1009 on the full self-adapting circuit and the PMONs to generate all the simulation results necessary to build the full query database 1010 that completely represents the relationships between all the dominant components and critical parameters 1003, inputs, and outputs of the analog circuit 1002, the process monitors PMON 1004, the voltage and the temperature over the complete range of PVT. As mentioned above, this full query database is a much more efficient representation of the design “knowledge base” compared to the thousands of data files spit out by simulation engines like SPICE, HSPICE, Spectre, Eldo, etc. The machine learning dataset 1011 is derived from the query database 1010 according to pre-defined rules.

The relationships between the input's dominant components, critical parameters, and PVT conditions and outputs circuit outputs, and circuit specifications are codified into a machine learning model 1012 of the analog circuit. The machine learning model is then trained 1012 with the machine learning dataset 1011. It is then verified to achieve the desired accuracy in step 1013 by comparing its predicted results against those obtained from simulations that are already stored in the full query database. In addition, a set of dedicated simulations on several self-adapting scenarios will be run to verify that the self-tuned circuits are indeed functional and meet the desired specifications 1015. If they do, the final circuit assembly, including the base analog circuit, the tuning circuit, the control block, and the PMON will be released to layout 1016. If problems are found with the functionality or accuracy of the self-tuned circuit, step 1012 is usually repeated, meaning the machine learning model is adjusted to resolve them. In some cases, changes to the base circuit 1002 or the tuning circuit 1005 might be necessary.

Typical analog circuits have multiple global specifications e.g., total power consumption, PSSR, several inputs and outputs, each with its own set of specifications input offset voltages, input currents, maximum output current, output slew rate, output frequency response, etc. FIG. 10B shows the design method of this disclosure to create self-adapting versions of those circuits.

The design method starts with the circuit specifications 1021 and the base analog circuit 1022 as before. This time, critical parameters and dominant components are identified for each global specification and each output specification. It is well known by those skilled in the art that changes in the electrical characteristics of the circuit components can have very different and potentially contradictory effects on the specifications of the analog circuit. Given the very large number of electrical parameters in the NMOS and PMOS transistors for example, and that analog circuits can include many such devices, the relationships become intractably complex. We simplify such problems by focusing only the critical parameters and the dominant components 1023. Although the effects of the changes in the critical parameters of the dominant components on the output specifications can be different and contradictory, the problem set is now confined. The design method continues in step 1024 with the creation of the simulation test bench which is the set of simulation tests with all appropriate stimuli, analyses, and outputs that the circuit designer will then create according to the desired PVT ranges, the inputs, and the outputs under analysis. This step also includes verifying that indeed the right critical parameters and dominant components are selected.

Based on the above selection, one or more appropriate PMON circuits are designed 1025 or picked from a library and verified that their variations indeed track those of the selected critical parameters and dominant components over the range of PVT changes 1026. Indirectly, they verify here also that the changes tracked by the PMONs also track the specifications of the outputs under analysis. The next steps, tuning circuit design 1027, control block design 1028, full circuit assembly 1029, full simulation test bench design 1030, and full circuit simulation 1031 are the same as those in FIG. 10A, except that there is a much larger number of variables, inputs, and outputs. The number of simulations is also much higher. The resulting full query database 1032 thus becomes more complex and larger but is still smaller than the full set of raw simulation results by order of magnitude. This again is where the method in this disclosure of using a query database is much more advantageous and efficient. Alternatively, the base analog 1022, PMON 1025, tuning 1027, and control block 1028 circuits as well as the ML models 1034 can all be picked from existing libraries to use as-is or with modifications to fit the current needs.

Based on the above knowledge, machine learning datasets 1033 are created for each output specification that needs to be self-tuned. Such datasets are then used to create and train 1034 a machine learning model and verified to be accurate 1035 for each desired output specification.

This method diverges at this point from that of FIG. 10A with the creation of a top-level hierarchical machine learning model. As discussed above, the circuit designer has created many output specifications. The behavior of each output specification over PVT is represented by its own machine-learning model. The top-level hierarchical machine learning model represents the behavior of the full analog circuit with all of its outputs and specifications. The remaining steps, including verification of model accuracy 1037, verification of self-tuned circuit functionality 1038, and decision-making 1039 of release to layout 1040 are the same as before. In cases where problems arise, changes are made to the applicable machine learning model of the affected output 1034 or the top-level hierarchical ML model 1036.

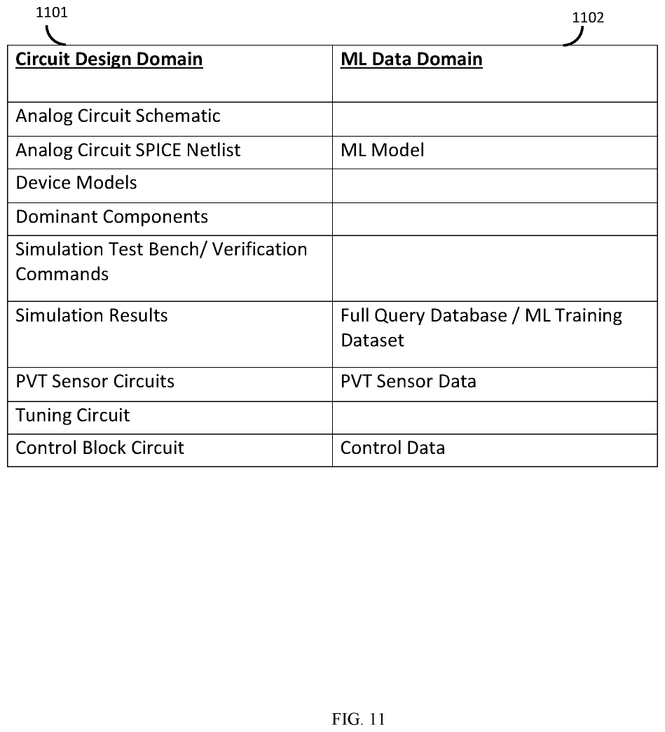

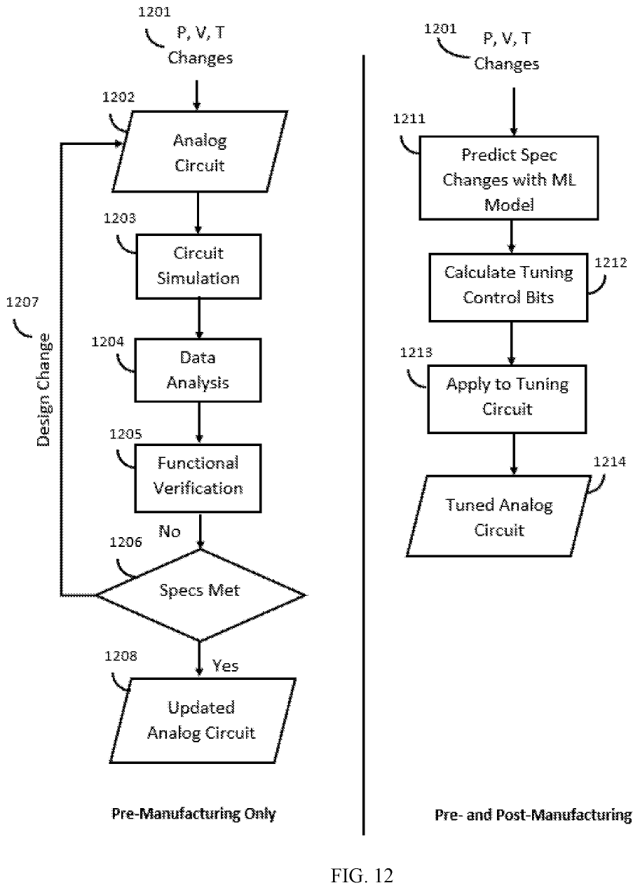

FIG. 11 is a diagram representing two ways to represent and manipulate the design-related data in the Circuit Domain and the ML Data Domain, according to the embodiments herein. FIG. 4 illustrates a key concept which is the differentiation between the traditional “circuit design domain” 1101 and the “machine learning data domain” 1102. The “circuit design domain” in the context of this disclosure includes all the design-related components like circuit schematic, SPICE netlist, device models, verification simulation results, etc. spanning across multiple design environments. In a computer system, these are computer files of various sizes stored in so-called design databases by those familiar with the art. The simulation results in themselves could occupy several tens of gigabytes. They could take hours or even days to generate from simulations run on powerful servers. Overall, the analog circuit, its various representations, and its behavior over PVT are represented traditionally in the circuit design domain by a huge collection of data files. Based on the conventional design method, design changes made in the circuit design domain, either to update the analog circuit design or to modify it in response to changes in PVT conditions, are slow and resource consuming. A change in the circuit schematic would cascade down to changing the SPICE netlist, running more simulations, and verifying the results, all resource and time-consuming work of FIG. 2. In contrast, the main elements representing the analog circuit and its associated behavior with respect to PVT in the machine learning data domain comprising of the machine learning model, the full query database, the ML training dataset, and the like, are much more efficient and easier to handle when changes need to be made according to FIGS. 10A and 10B.

Furthermore, every analog circuit can be represented or “modeled” by a SPICE netlist describing transistors, resistors, capacitors, and other circuit elements, along with their inter-connections and their electrical models. As discussed above, SPICE and other circuit simulation programs take such netlist, add the simulation commands, and translate the resulting relationships into nonlinear differential equations that can be solved using implicit integration methods, Newton's method, and sparse matrix techniques. Solving those complex sets of equations as we know requires long simulation runs on high-performance and power-hungry servers and disk drives. By its nature, the SPICE netlist in the circuit design domain does not describe the behavior of the analog circuit, the interactions between its various components, their electrical parameters, and the electrical specifications of the circuit over the PVT conditions. Extensive simulations are needed to derive such behavior and interactions. The analog circuit's machine learning model in the ML data domain is a big step up from the SPICE netlist as it fully represents the circuit behavior and the interactions between its various components over PVT. It is a very efficient and accurate representation because it has distilled all the complex relationships obtained from the full query database. In our case, the other main advantage of the machine learning model is the emphasis only on the critical device parameters of the dominant components while the rest of the parameters and components are ignored. To even increase further the efficiency, only the correlations between the changes in the critical parameters of the dominant components, the changes in process, voltage, and temperature, and the corresponding changes of the analog circuit output specifications are modeled using Pearson coefficients.

By using the efficient machine learning model, designers can create and verify design changes much faster and more efficiently within the ML data domain. The log file in

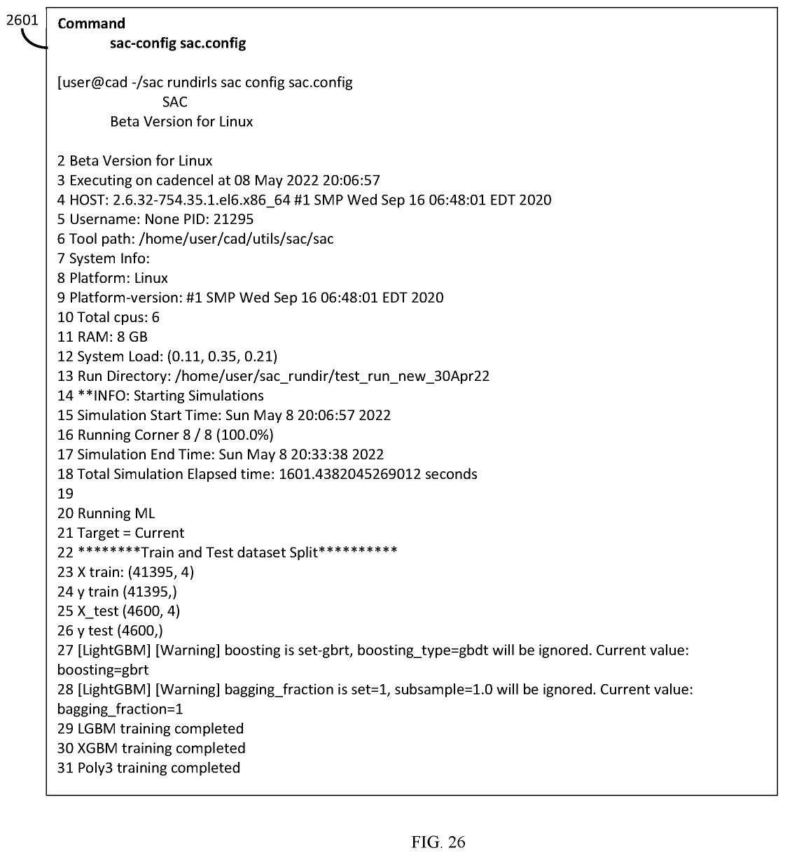

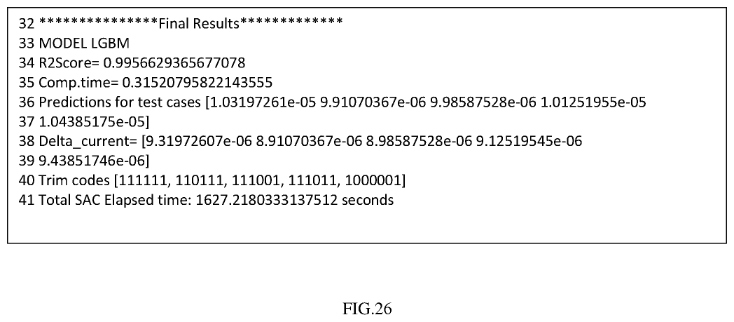

FIG. 26 will show that for the current reference in FIG. 1B, the computer time to fully simulate the circuit over the required PVT conditions is 1,601 seconds. Meanwhile, the total time to collect simulation data, create and train three ML models, pick the best one, predict the specification changes for new PVT conditions, and generate the change control bits to negate those changes is just 26 seconds.

Furthermore, the full query database, the ML training data, and the ML model can all be easily updated or expanded for more PVT conditions or specifications with additional simulation results. In addition, the ML data domain is much more flexible to handle. For example, new machine learning models can be derived from the same query database to describe new output specifications not previously modeled. The top-level ML model that includes many lower-level models can also be changed to put emphasis on different specifications during the self-adapting process. Such changes can be done in the ML data domain very efficiently without going back to the circuit design domain.

FIG. 12 is a flow diagram that illustrates for comparison the two methods for making analog circuit design changes in the Circuit Design Domain and ML Data Domain. FIG. 12 depicts the efficiency of the design change process in the ML data domain as compared to the circuit design domain. With the conventional method in the circuit design domain, if the design does not meet specifications for a certain PVT condition, the circuit designer must go through the full design change loop 1207 between steps 1202 and 1206 to update the circuit 1208. As discussed above, changes performed in the circuit design domain are still at high risk, slow and resource intensive. Therefore, it is a well-known industry practice to finalize the changes before the design is sent to layout for manufacturing. In the ML data domain, the design system uses the ML model to predict the specification changes step 1211 caused by changes in the PVT conditions. The system then generates the tuning control bits 1212 and applies them to the tuning circuit step 1213. As a result, the circuit is tuned in step 1214 to bring the specifications in the new PVT conditions back to nominal specified values. Since the ML learning model is created from simulation results, the new tuned circuit is already assured to work. The change process is inherently a closed-loop one. Further, steps 1211 to 1214 are performed rapidly and efficiently in the ML data domain either in the design phase or after manufacturing of the analog circuit.

Once the ML model is created and trained, the circuit designer can use it during the design process to predict the changes in the specifications of the analog circuit under any new PVT conditions 1211. The circuit designer can calculate through the design system the appropriate tuning control bits 1212 to apply to the tuning circuit 1213 to adjust the dominant components to tune the analog circuit step 1214, i.e., to bring its specifications back to the nominal values.

The machine learning model can also be used to make changes on-the-fly to the analog circuit after it is manufactured on silicon. In that case, a connected CPU storing the ML model of the analog circuit can predict the circuit specifications under any new PVT conditions encountered step 1211. The CPU will then calculate the tuning control bits step 1212 and apply them to the tuning circuit step 1213 attached to the analog circuit to change its dominant components to bring the specifications of the analog circuit back to the nominal values step 1214. Therefore, steps 1211 to 1214 performed in the ML data domain are very fast and efficient compared to all the steps 1201 to 1208 performed in the circuit design domain.

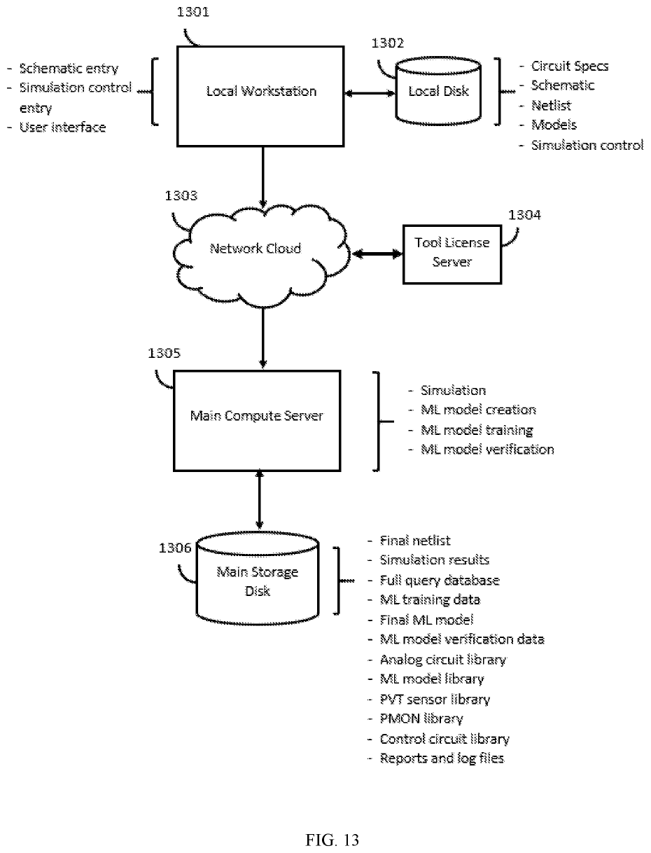

FIG. 13 is a block diagram illustrating a Computer System for the design of self-adapting analog circuits (SAC) design system, according to embodiments herein. Typical analog design tasks like schematic entry and simulation control entry are performed through a user interface on the local workstation 1301. The local disk 1302 stores the circuit specs and the design-related information like the circuit schematic, the SPICE netlist, the device models, the simulation control, etc. A typical analog design workstation requires several commercial design tools from companies like Cadence, Synopsys, etc. Licenses to those design tools are stored in a tool license server 1304 connected to the local workstation via the network cloud 1303. Small simulation runs are performed on the local workstation 1301 and large simulation runs are on the more powerful main compute server 1305 armed with much more space from the main storage disk 1306. All other compute intensive tasks like ML model creation, training and verification are done on the main compute server as well. The main storage disk 1306 is the repertory of all the required input components libraries of analog circuits, PVT sensors, PMONs, control circuits, data simulation data, full query database, ML training data and results final netlist, final ML model, reports, and log files generated in the design process presented here.

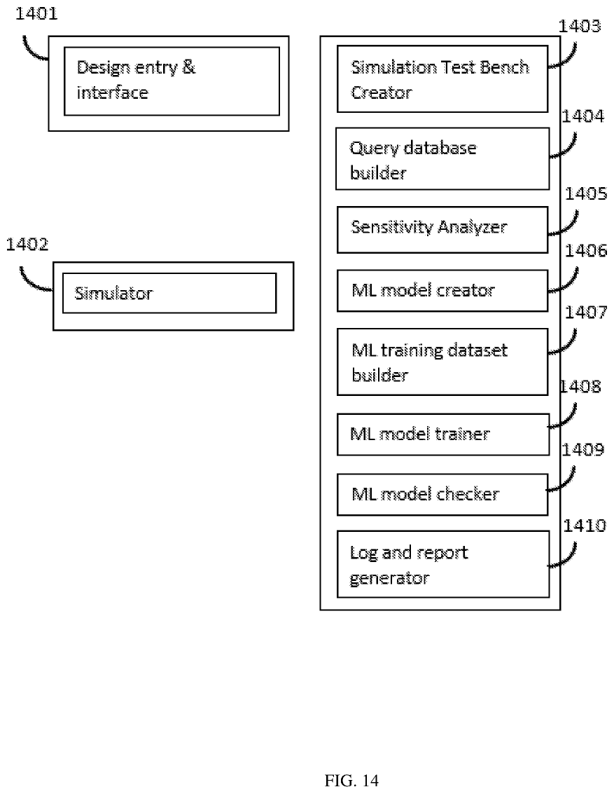

FIG. 14 is a block diagram illustrating modules in self-adapting analog circuits SAC Design System to create the ML Model for self-adapting analog circuits, according to embodiments herein. On the left side are the design entry and interface module 1401 residing in the local workstation, and the simulator 1402 usually residing on computer servers connected via the cloud to the local workstation. The right side shows the main modules that are executed to create and verify the self-adapting analog circuit. Some or all the modules can reside either on the local workstation or on the computer servers depending on the complexity of the analog circuit being designed. The simulation test bench creator 1403 will take the simulation configuration and control directives the design circuit designer enters in the design entry and interface module 1401 to create the complete simulation test bench applicable to the specific simulator SPICE, Spectre, HSpice, and the like. After the simulations are run, the full query database builder 1404 will take the results, organize, and format them into a full query database that efficiently and completely represents the relationships between all the dominant components, inputs and outputs of the analog circuit, the process monitors PMONs, the applied voltage and temperature over the complete range of PVT conditions. Data from this full query database will be pulled for use in all the subsequent steps. As discussed above, high efficiency, high accuracy and compact machine learning models are achieved by using the Pearson coefficients to describe the correlations between the changes in the critical parameters of the dominant components, the changes in the PVT conditions, and the corresponding changes in the outputs. The sensitivity analyzer 1405 takes the simulation results from the full query database 1404 and computes all the appropriate Pearson coefficients to send into the ML model creator module 1406 which will analyze and select the best fit among the various possible types of machine learning models. Based on the inputs and outputs, the Pearson coefficients, and the selected ML model, the ML dataset is built 1407, typically 90% of which will be used to train the ML model 1408 and 10% to test it 1409. Finally, all the process steps are logged, and the results are reported at 1410.

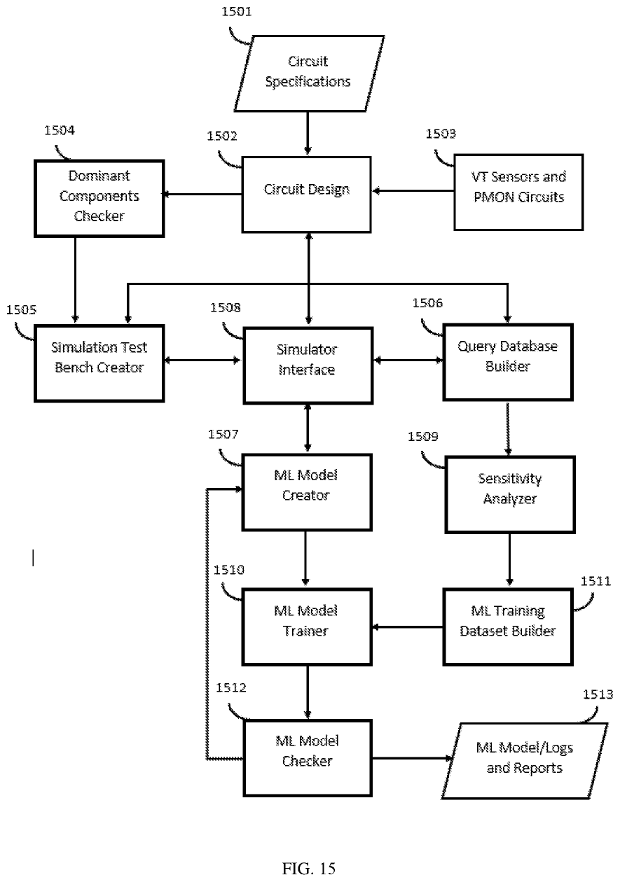

FIG. 15 is a flow diagram illustrating the interaction between modules of the SAC Design System to create the ML model for a self-adapting analog custom circuit, according to the embodiments herein. In the current context, a custom analog circuit is a completely new circuit that has not been created before. The circuit specifications over the desired PVT range 1501 are the starting point for the Circuit Design module 1502. Using the same analog design tools, the temperature and voltage sensor and PMON circuits 1503 are designed and fed into the Circuit Design module to build the full circuit for simulation and ML model creation 1507. Such module in this design system would include a user interface and an application interface to a commercial design system from Cadence or Synopsys, etc. for schematic entry and netlist creation. Once the full analog circuit is created from the Circuit Design module, the dominant components checker 1504 uses targeted simulations of the analog circuit to verify that the critical parameters and dominant components selected by the designer are indeed the right ones. That list is provided to the Simulation Test Bench Creator 1505 to create the appropriate test bench command and control files including the appropriate stimuli, analyses, and outputs so that the simulation runs would cover all the desired PVT ranges, the inputs, and the outputs under analysis. The Simulator Interface module 1508 allows the system to manage all the interaction between the circuit, the test bench, the ML model, and the query database. Via the Simulator Interface module, the Query Database Builder module 1506 takes all the results from the simulator and distill them into a Full Query Database that stores all the relationships between all the dominant components, inputs, and outputs of the analog circuit and of the process monitor PMON, voltage, and temperature over the complete range of PVT. By user's instruction or automatically, the ML Model Creator 1507 takes the list of input and output variables to create an ML model for the analog circuit. As discussed above, there are many types of ML models that can be applied. In this disclosure, the well-known polynomial model and the regression-ensemble model are used. Sensitivity analyses executed in the Sensitivity Analyzer module 1509 use the Pearson Coefficient method to describe the correlation between the changes in the output variables, the changes in PVT, and the changes of the input parameters. This focus on the changes rather than the actual values of the input and output variables allows the creation of simple yet accurate machine learning models of the analog circuit. Such simplicity also reduces computation resource and time. Sensitivity results are sent to the ML Training Dataset Builder 1511 for organizing and formatting into a Training Dataset.

The Training Dataset as discussed above consists of two sub-sets: the training set representing 90% of the cases and the test set consisting of 10% of the cases. The trained ML model from the ML Model Trainer module 1510 is then verified to be correct and accurate by the ML Model Checker 1512. If the checking fails, the ML model is refined in the ML Model Creator module. The final result is an accurate ML Model 1513 of the analog circuit, accompanied by log and report files. It is worth emphasizing here that all the modules discussed above 1504 to 1512 are run automatically on the design computer system.

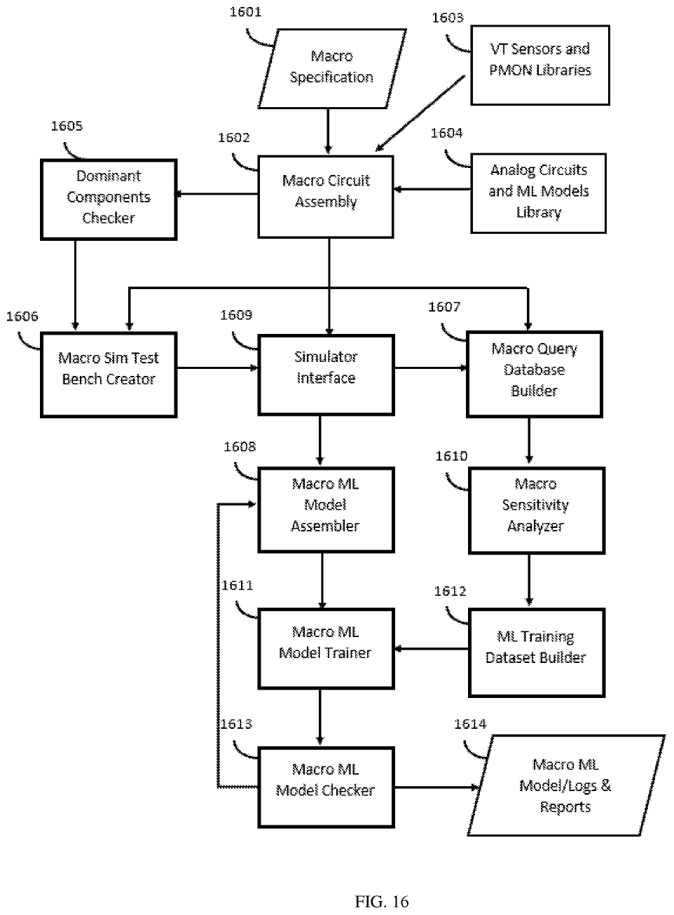

FIG. 16 is a flow diagram illustrating interaction between modules of the SAC Design System to create the hierarchical ML Model for a self-adapting analog macro circuit with several sub-blocks from a circuit library, according to embodiments herein. In the current context, an analog macro circuit assembly 1602 is a new analog circuit built from a number of smaller analog circuits pulled from an analog circuits and ML models library 1604, specifications extracted from a macro specification module 1601 and VT sensors and PMON libraries 1602. Each of those comes with all its design data such as schematic, netlist, ML model, etc. An example of an analog macro circuit is the phase locked loop that includes several smaller circuits like a voltage-controlled oscillator, phase detector, loop filter, etc. pulled from an existing library and connected. The analog macro would be much more complex, have multiple specifications, and would require the hierarchical ML model creation method shown in FIG. 8. All the remaining modules, including, but not limited to, dominant components checker 1605, macro sim test bench creator 1606, macro query database builder 1607, simulator interface 1608, macro ML model assembler 1609, macro sensitivity analyzer 1610, macro ML model trainer 1611, ML training Dataset Builder 1612, Macro ML Model Checker 1613 and Macro ML model/logs reporter 1614 perform the same way as those in FIG. 15. FIG. 16 shows that the method and system in this disclosure are applicable to multiple types of analog circuits, from very simple to very complex ones, thanks to the hierarchical ML modeling method described in FIG. 8. Those trained in the art would appreciate that there are other possible embodiments of the SAC design system that might include other modules or might not include all the modules shown.

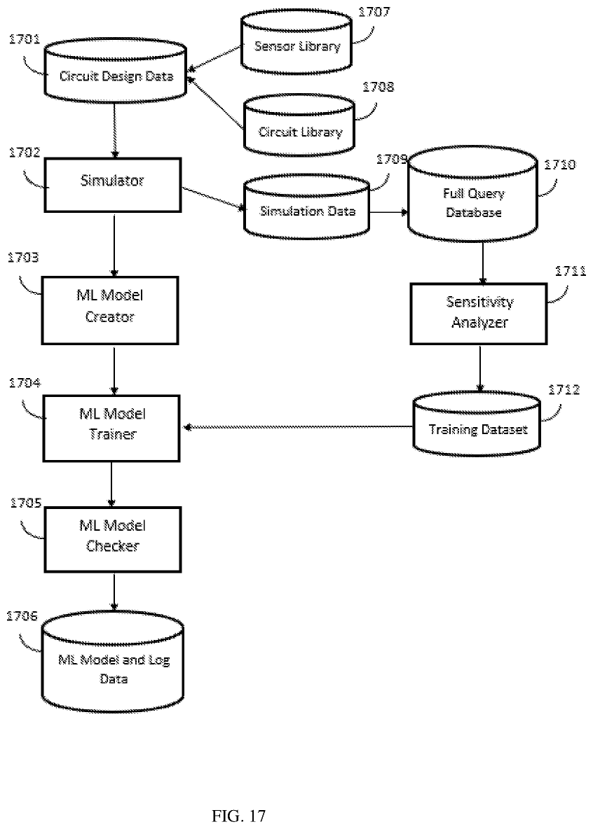

FIG. 17 is a flow diagram illustrating ML data generation and data flow of SAC Design System to create the ML Model of a self-adapting analog macro circuit, according to embodiments herein. The input data sets are from the circuit design domain; circuit design 1701, sensor library 1707, and circuit library 1708. As discussed before, the Simulation Data 1709 which can be very large is distilled into the Full Query Database 1710 The sensitivity analyzer 1711 provides the Pearson coefficients relating the input changes to the output changes under various PVT conditions and creates the Training Dataset 1712 used and checked by the ML model trainer 1704 and ML model checker 1705. The final results are a database containing the ML training data, the trained ML model, and the run log and report data 1706. The data flow of the design system is already discussed above when describing the module interactions in FIGS. 15 and 16.

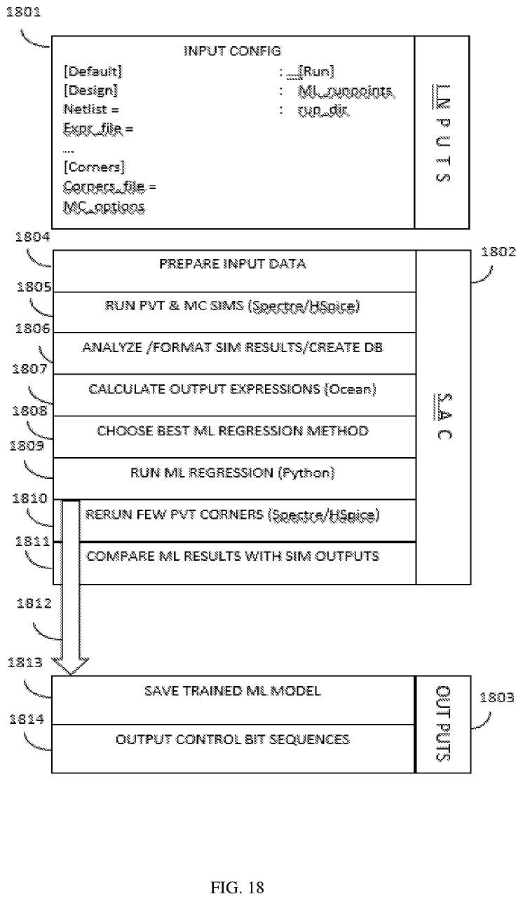

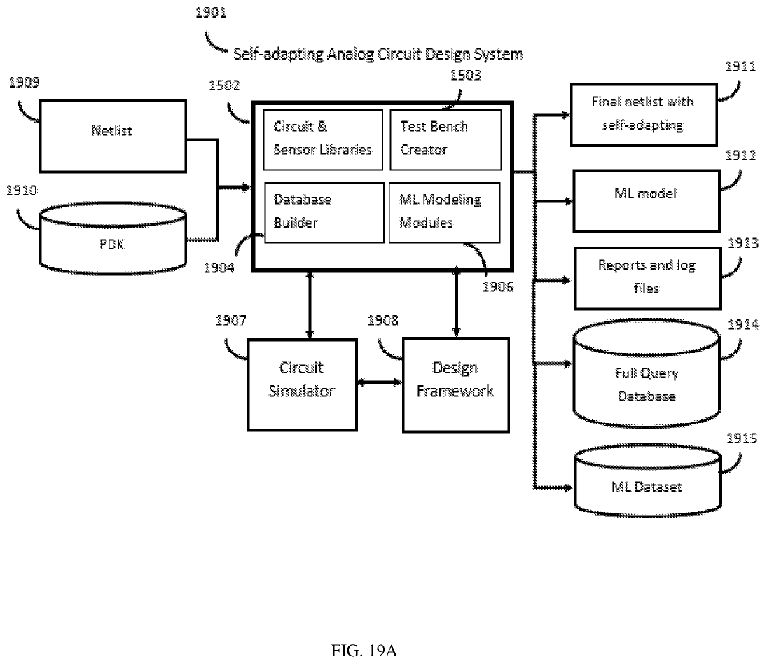

FIG. 18 represents the SAC-based design flow to create the ML model of a self-adapting analog circuit, according to the embodiments herein. There are three main sections: inputs 1801, SAC 1802, and outputs 1803. Input Config in 1801 is the required input configuration file the user needs to create to provide all the necessary information about the design environment, analog circuit, the PVT corners, the required analyses, etc. The design system would then prepare the input data step 1804 and run the needed simulations and analyses step 1805. In one embodiment described here, simulations are run with the Spectre or HSpice programs over the specified PVT conditions and Monte-Carlo analyses are performed within those programs. The simulation results are then analyzed, formatted and entered into the full query database step 1806. In step 1807, OCEAN scripts are run on the simulation results to calculate the output expressions. OCEAN stands for Open Command Environment for Analysis is a programming language that can automate simulations and result analysis within Cadence's analog design environment. For example, the value of the reference current I_{ref} as a function of variables P, V and T is calculated for each PVT combination. The design system then chooses the best machine learning regression method based on its analysis and testing of the data and the output expressions step 1808. The user can also direct it to use any ML regression method available. The result of the ML regression module is the machine learning model of the analog circuit which is then saved step 1813. The system performs a quality check of the regression results by re-running simulations with a few selected PVT conditions on Spice, or Spectre or HSpice step 1810 and compares the results predicted from the ML model to those from simulation step 1811. If the results match within the desired tolerance, the ML model is accepted and saved step 1813. The system then calculates the values of the outputs under the new PVT conditions for example, slow process corner, 0.7V supply,-55° C., and compares them to the values at nominal conditions typical process corner, 27 C, 0.8V supply, 27° C. From the differences, the system will calculate the control bits required to shift the values of the dominant components to compensate for the changes. By applying the control bits, the system will come up with the new values of the dominant components. It will then plug them into the netlist and re-run the simulations with those updated values. If the simulation results show that the output values are corrected to be close to those under the nominal specifications, the machine learning model is considered accurate.

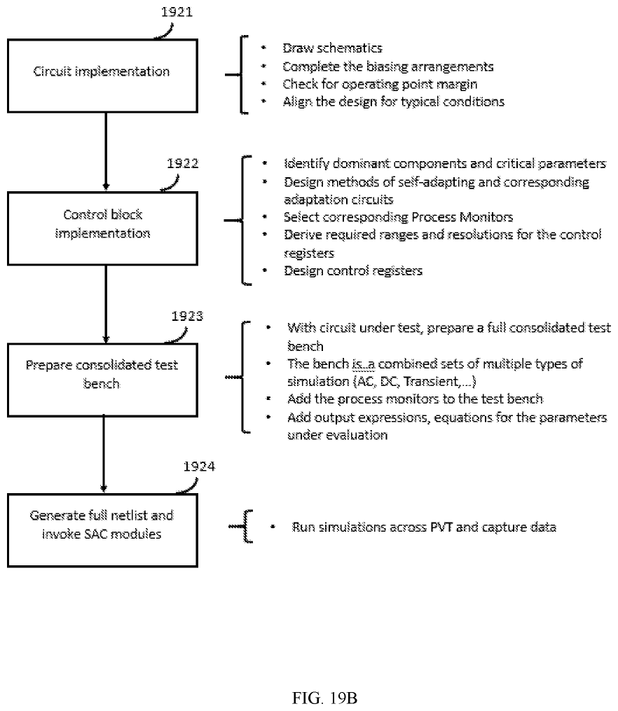

FIG. 19A is a block diagram illustrating various modules of an embodiment of the SAC Design System for self-adapting analog circuits, according to embodiments herein. The SAC Design system consists of four main components. The circuit and sensor libraries 1902 include the various analog circuits and PVT sensors that the design system already has stored and made available to the designer to use as-is or to modify. The circuits and sensors also come with all the design databases like schematics, netlists, models, test benches, full query databases, and ML models. The Test Bench Creator block 1903 takes all the full circuit design data and the command inputs from the designer to create the complete test bench for the required simulations and generate the full set of data needed to build the Full Query Database 1914 through the Database Builder block 1904. The Database Builder block 1904 comprises of internal modules comprising, but not limited to data collecting, data formatting, dataset splitting, data testing, and quality analysis. The ML Modeling module 1906 comprises of, but not limited to ML model creation, evaluation, training, verification, and the like.

The SAC design system interfaces with the Circuit Simulator 1907 and the Design Framework 1908 to create a seamless design environment for the circuit designer. For example, the circuit designer creates the analog circuit database, enters the schematics, and generates the netlist in the Design Framework 1908 then invokes from the design environment the Circuit Simulator 1907. A commercial example of the Design Framework is ADE, for Analog Design Environment, from Cadence. The two main inputs to the SAC design system are the netlist as created from the schematic and the PDK, for Physical Design Kit. The PDK is a database provided by each silicon foundry for a particular process technology that includes all the needed information and files necessary for the physical design of integrated circuits on that process. More specifically, the design system herein reads from the PDK the SPICE model parameters of the devices used in the netlist so that simulations can be run. The first output of the design system is the final netlist of the full self-adapting analog circuit including the base circuit, the control circuit, and the tuning circuit. The other outputs are the fully verified machine learning model 1912 and the relevant reports and log files 1913. Also obtained from the design system are the Full Query Database 1914 and all the relevant data files related to the ML model 1915.

FIG. 19B is a flow diagram of a front-end design method for self-adapting analog circuits, according to embodiments herein. The circuit implementation 1921 involves first drawing the schematics of the analog circuit, together with the biasing arrangements like references, start-up circuits, and the like for it to function properly. Secondly, the operating point margin is checked. As the operating point of the circuit moves with PVT conditions, there should be enough margin in the biasing of the devices to ensure they operate within their desired operating domains. For example, the biasing must be calculated such that a transistor designed to work in the saturation mode would not enter the linear region in any of the PVT conditions. Otherwise, the analog circuit might no longer function correctly. The next task is to align the design to meet all the specifications for typical PVT conditions. Since the design has enough operating point margin over PVT, it will have a great chance of operating over the full PVT conditions. However, it will have specifications significantly different from those at the nominal conditions. Functionality over the range of PVT conditions will make it easier to later re-tune or self-adapt the circuit.

The first task of control block implementation 1922 is to identify the dominant components and critical parameters. The self-adapting method and the corresponding adaptation or tuning circuits solely depend on the critical parameters and dominant components. The next major task is to prepare the consolidated test bench 1923. The full consolidated test bench is the combined set of multiple types of simulation needed to capture all the relationships between the input and output variables. The selected process monitors are also added. Finally, the output expressions and the equations needed to calculate the parameters under evaluation are added. For example, one might want to find the changes of the instantaneous output conductance rho of a certain NMOS over the PVT range. The output expression for rho is drain current divided by the drain to source voltage. Finally, the circuit designer creates the full netlist 1924 including the base analog, control, and tuning circuits together with the PMON circuits then invoke the rest of the modules of SAC, the Self-Adapting Circuit design system described in FIGS. 14 to 19A.

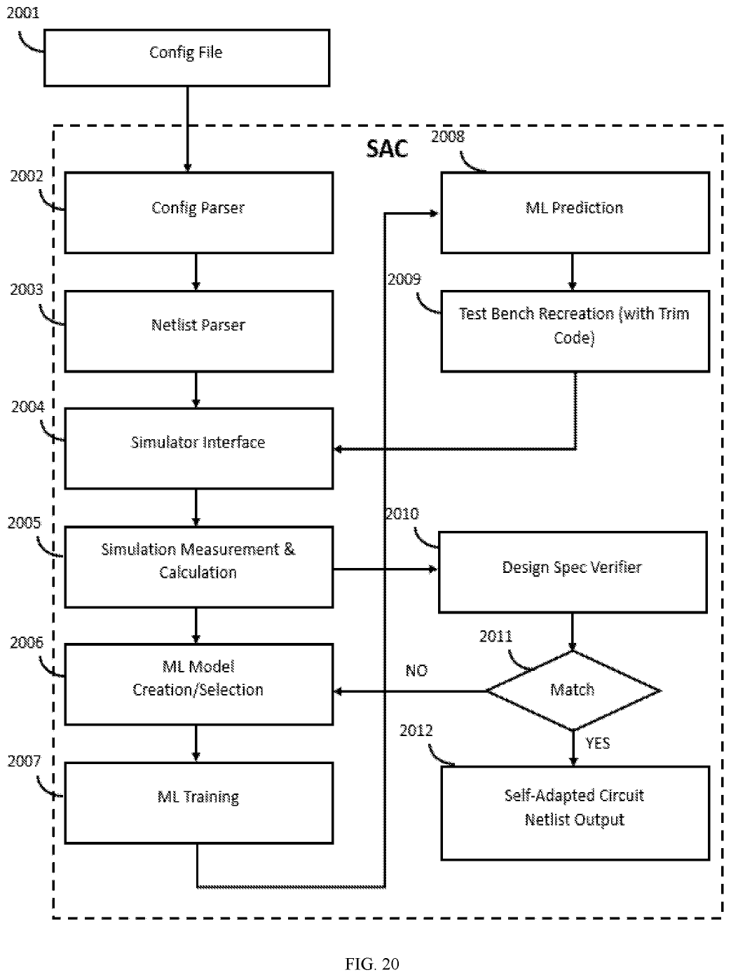

FIG. 20 is a flow diagram illustrating various Modules of an implementation of the SAC Design System for self-adapting analog circuits, according to embodiments herein. The system starts with reading the configuration file 2001 created by the design circuit designer for the analog circuit. The configuration file gives the system all the relevant information to start. The configuration file will be parsed by the Config Parser module 2002 for the system to extract all the useful information and set itself up. The analog circuit netlist will be parsed next 2003 then the results sent to the Simulator Interface module 2004 that drives all the simulation runs. The desired output values as measured from the simulation results 2005 are cataloged and sent to the ML Model Creation/Selection module 2006 where one or more ML models are created. Using certain criteria like accuracy, speed of convergence, complexity, etc, the best ML model candidate is selected and sent to the ML Training module. It should be noted that the user can select one or more of the ML models for training 2007. The ML Prediction module 2008 will use the newly trained ML model to predict the outputs for a certain PVT condition. The ML Prediction module 2008 then compares those values to the output values under nominal PVT. Based on the differences found, the ML Prediction module 2008 calculates the values of the control bits, the trim code that will be applied to the adaptation or tuning circuit to bring the output values back close to nominal. The Test Bench Recreation module 2009 receives the trim code and recreates a new testbench to be sent to the Simulator Interface module where new simulations are run. The new simulation results are then sent to the Design Spec Verifier module 2010 which should confirm that the applied trim code has actually changed the outputs to close to the desired nominal values. If the desired accuracy is not achieved, the SAC system directs the ML model to be adjusted 2006 and the loop starts again. If there is a “match” 2011, the self-adapting circuit netlist output is generated 2012.

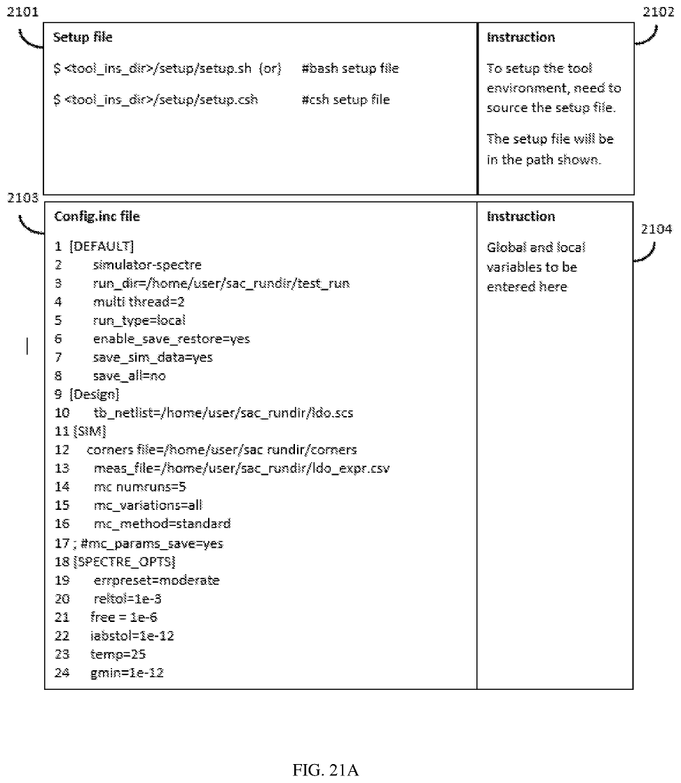

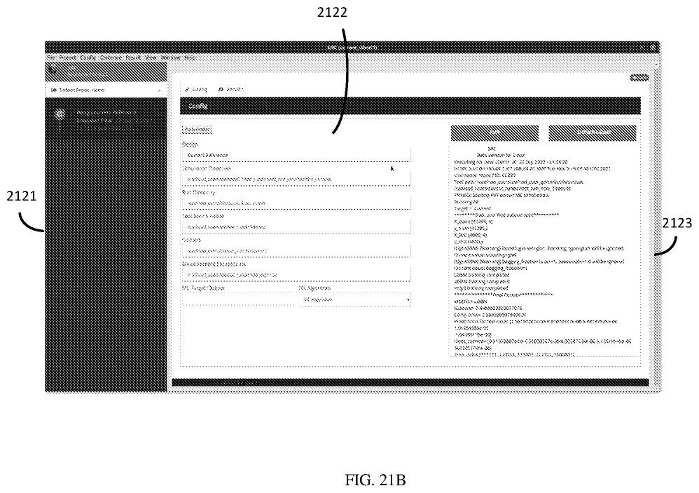

FIG. 21A is a schematic representation of samples setup and configuration files of SAC Design System as seem on a circuit designer's screen, according to embodiments herein. The set-up file 2101 is on the left panel and the user instruction is on the right 2102. Next are the configuration file shown on the left panel 2103 and the user instruction on the right 2104. The configuration file instructs the system about the simulator, the run directory, the PVT corners, the measurements, the types and numbers of simulations to run, etc. This file gives the system all the relevant information to work. FIG. 21B is a screenshot of the Graphical User Interface (GUI) of SAC Design System, according to an exemplary illustration of the embodiments herein. The GUI as shown in FIG. 21B illustrates information about the design on the left side and the results of the ML model creation and training run, and the trim codes for PVT test cases on the right.

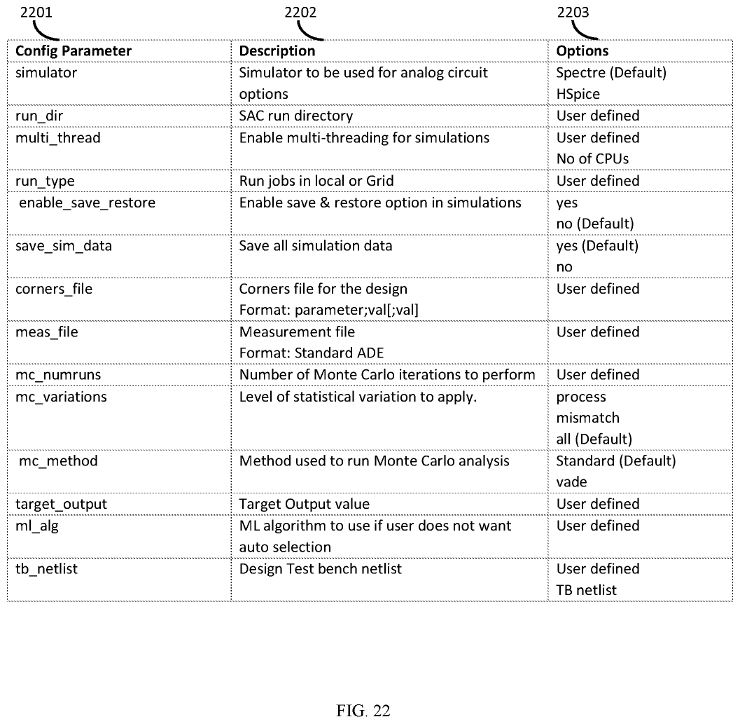

FIG. 22 represents a configuration control file of the SAC Design System, according to an exemplary illustration of the embodiments herein. The various items of the configuration file including, but not limited to, the configuration parameters 2201, their descriptions 2202, and the various user options 2203 are shown in FIG. 22.

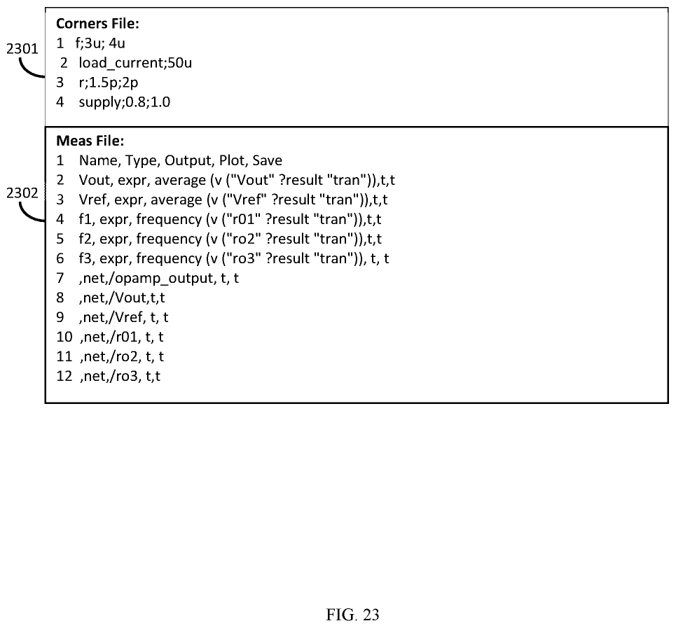

FIG. 23 represents corners and measure control files of the SAC Design System, according to an exemplary illustration of the embodiments herein. FIG. 23 shows examples of the corners file 2301 specifying the ranges of PVT and the measurement control file 2302 specifying the output variables of the simulation runs for the current reference circuit of FIG. 1B above.

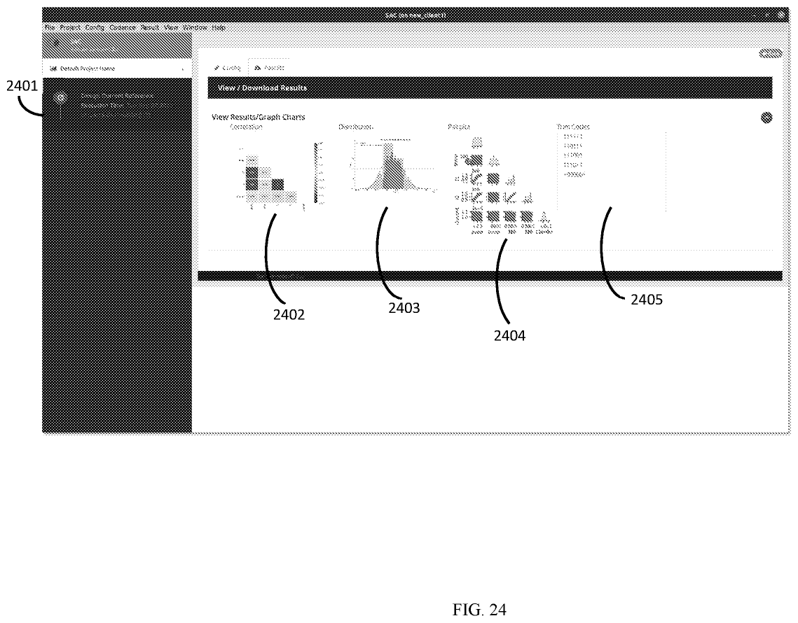

FIG. 24 is a screenshot of GUI showing the results of ML Modeling from the SAC Design System, according to an exemplary illustration of the embodiments herein. FIG. 24 is a screenshot of the GUI 2001 showing the intermediate results, graphs of the correlation factors between input variables 2402, the distribution charts between predicted and simulated output values 2403, the pair plots between the outputs and the values of the dominant component R1 2404, and the trim codes 2405 for the test cases being run.

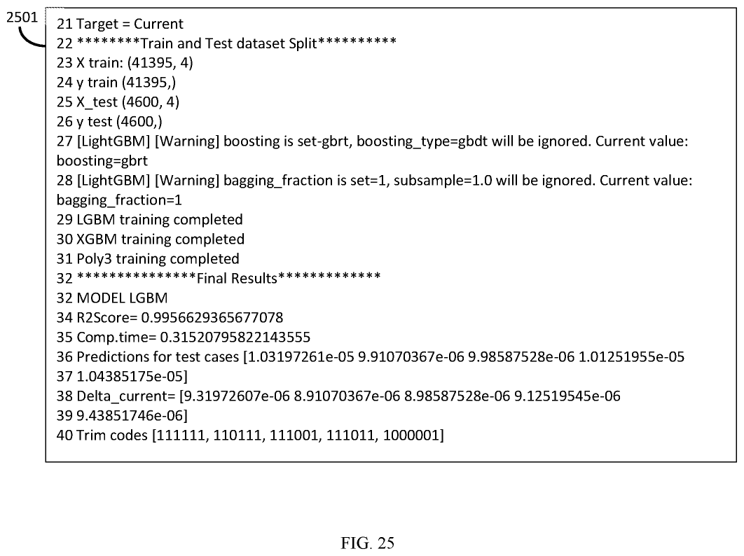

FIG. 25 represents details of ML Model training results, according to the embodiments herein. FIG. 25 shows the results of ML model training for the current reference circuit as executed on the design system 2501. Line 21 indicates the target for training is the reference current. Lines 23-26 show that 41,395 samples simulation results were used for training and 4,600 samples for testing. Lines 27-28 show some warnings about the parameters of LightGBM training. Lines 29 to 31 show all three training methods LGBM, XGBM, and Poly3 were completed. The Final Results section shows the results for the LGBM model. The R2score, a key measure of accuracy for the ML model is very close to 1. Line 35 shows the computer time is just 0.31 seconds. Line 36 shows the predicted reference currents after self-adapting are very close to the target of 10 uA. Line 38 shows the predicted currents before self-adapting. As discussed before, the design system first predicts from the ML model the values of the reference current before self-adaptation under the various PVT conditions and then compares them to the desired nominal value of 10 uA. Based on the differences, it will calculate the desired changes in the resistor values for each of those conditions and use them to again predict the values of the current reference after tuning. Since the after-tuning current values are very close to the nominal value, the tuning is successful, and the system will output the trim tuning control codes in line 40.

FIG. 26 represents a log file showing the training process and results of ML model, according to the embodiments herein. The system training is conducted on a small 6-CPU server with a total runtime is 1627 seconds of which 1,601 seconds were for simulation and just 26 seconds for the complete ML training and testing process.

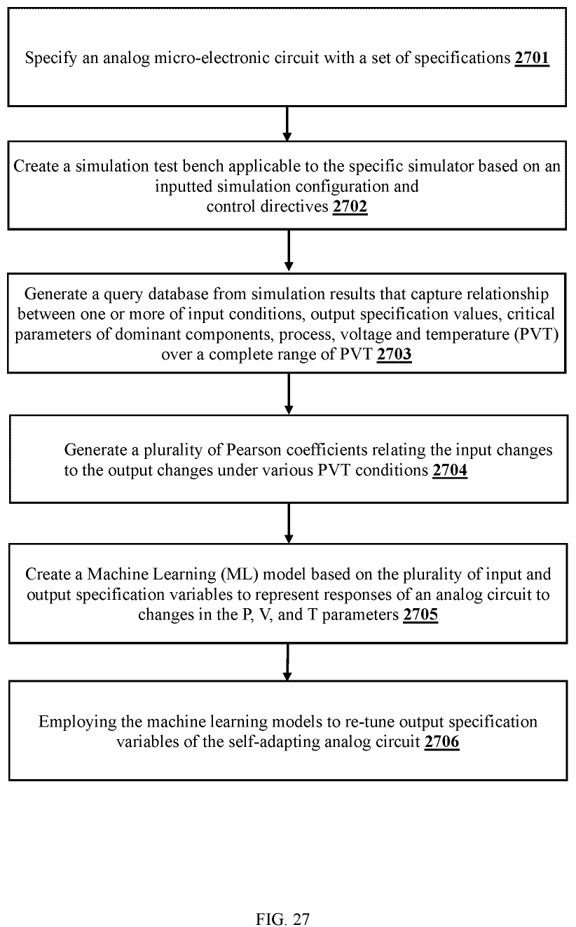

FIG. 27 is a flow chart illustrating a method of creating a self-adapting analog micro-electronic circuit, according to the embodiments herein. The method comprises of, at step 2701, specifying an analog micro-electronic circuit with a set of specifications. At step 2702, a simulation test bench creator module creates a simulation test bench applicable to the specific simulator based on a provided simulation configuration and control directives. At step 2703, the database builder generates a query database from simulation results that capture the relationship between one or more of input conditions, output specification values, critical parameters of dominant components, process, voltage, and temperature (PVT) over a complete range of PVT. At 2704, a plurality of Pearson coefficients relating to changes in input to output variables under various PVT conditions are generated. The Machine Learning (ML) creator module creates a Machine Learning (ML) model based on the plurality of input and output specification variables to represent responses of an analog circuit to changes in the P, V, and T parameters at 2705 and creates a self-adapting analog circuit to re-tune its output specification variables employing the ML models at 2706. Here re-tuning the output specification variables comprises estimating using the ML model, values of the critical parameters of dominant components required to re-tune the specifications of the analog circuit to predetermined nominal values.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the appended claims.

What is claimed is:

1. A method of creating a self-adapting analog micro-electronic circuit, the method comprising:
specifying (2701) an analog micro-electronic circuit with a set of specifications;
creating (2702), by a simulation test bench creator module, a simulation test bench applicable to the specific simulator based on an inputted simulation configuration and control directives;
generating (2703), by a database builder, a query database from simulation results that capture relationship between one or more of input conditions, output specification values, critical parameters of dominant components, process, voltage and temperature (PVT) over a complete range of PVT;
generating, by a sensitivity analyzer, a plurality of Pearson coefficients relating the input changes to the output changes under various PVT conditions;
creating (2705), by a Machine Learning (ML) creator module, a Machine Learning (ML) model based on the plurality of input and output specification variables to represent responses of an analog circuit to changes in the P, V, and T parameters; and
creating (2706) a self-adapting analog circuit adapted to re-tune output specification variables applying the ML models, wherein retuning the output specification variables comprises estimating using the ML model, values of the critical parameters of dominant components required to re-tune the specifications of the analog circuit to predetermined nominal values.

2. The method of claim 1, wherein creating (2706) a self-adapting analog circuit configured to retune its specifications to predetermined nominal values, the method comprising:
creating an original netlist for a base analog micro-electronic circuit conforming to the specifications;
selecting one or more critical parameters of the dominant components;
designing a control circuit block co-located with the base analog micro-electronic circuit;
designing a tuning circuit block co-located with the base analog micro-electronic circuit;
assembling a full circuit comprising the base analog micro-electronic circuit, the control circuit block, and the tuning circuit block;
creating a test bench of the full circuit;
simulating the full circuit with the test bench;
analyzing and formatting the full query database from simulation results obtained through simulating of the full circuit;
creating a machine learning ML training database from the data analyzed and formatted in the previous step;
creating and training the ML model;
predicting results using the ML model and inputting associated control data to the control circuit;
directing, by the control circuit, the tuning circuit to change the dominant components in a way to re-tune the specifications of the analog circuit to predetermined nominal values;
verifying the functioning of the ML model; and
testing whether the function of the re-tuned circuit conforms to the specifications, and if not, repeating the steps of creating and training an ML model; and
releasing to layout for semiconductor fabrication the full circuit, wherein, a self-adapting analog circuit is configured to change its internal components on-the-fly in response to changes in process, voltage, and temperature parameters to re-tune its specifications that have deviated back to the predetermined nominal values.

3. The method of claim 1, wherein creating (2705) an ML model further comprising:
selecting the ML model from an ML library of previously created and trained ML models according to one or more criteria such as L1norm, or L2norm, or r2 score and compute times;
accessing the data file of previously created ML training databases; or
accessing and selecting the ML model from a library comprising previously stored analog circuit, control block and adaption circuit designs.

4. The method of claim 1, further comprising:
implementing a base analog circuit topology by drawing the analog circuit in a composure window, completing any biasing arrangements, checking for operating point margins, and aligning the design for preferred PVT conditions.

5. The method of claim 1, wherein generating (2703), by the database builder, a query database from simulation results comprises of:
running simulations across PVT and capture data, distilling and formatting the simulation data into the full query database representing the relationships between the inputs, the critical parameters of the dominant components, and the output specifications over all the simulated PVT conditions.

6. The method of claim 1, wherein generating (2703) the query database further comprises:
using Pearson coefficients to describe correlations between the changes in the output specifications, the changes in PVT conditions and the changes in the critical parameters of the dominant components; and
deriving from the full query database a machine learning dataset containing only the data describing the correlations between the changes of the output specifications and the changes of the critical parameters of the dominant components over all the simulated PVT conditions.

7. The method of claim 1, wherein further comprising creating an ML data domain representing each self-adapting analog circuit, where the ML data domain comprises one or more of the ML models of the analog circuit, the full query database unique to the analog circuit distilled from simulation results, the ML training dataset for the analog circuit, the PVT sensor data as received from the sensors, and the control data to re-tune the analog circuit for requisite PVT conditions.

8. The method of claim 7, further comprising changing design of analog circuits in the ML data domain through one or more of:
using sensor data to determine new PVT conditions encountered,
using the ML model to predict the specifications under the new PVT conditions, calculating differences between the specifications under the new PVT conditions and the specifications under nominal conditions,
using the ML model to estimate the values of the critical parameters of the dominant components required to re-tune the specifications back to their values under nominal conditions,
determining the control data required to change the dominant components such that the specifications of the analog circuit under the new PVT conditions are changed back to their values under nominal conditions, and
providing the control data to the tuning circuit to re-tune the analog circuit.

9. The method of claim 1, further comprising updating the ML model of the self-adapting analog circuit before tape out or on silicon, the method comprising one of:
changing a self-adaptation method, or formulae, or equations;
changing a level of accuracy of any self-adapted specifications;
expanding or reducing a range of PVT conditions for self-adaptation;
adding input variables or output specifications for self-adapting; or
changing emphasis on a set of specifications over other specifications for self-adapting.

10. The method of claim 1, wherein creating the self-adapting analog circuit comprising at least one of:
creating a self-adapting analog circuit comprising several smaller circuits; and
using a single top-level machine learning model to re-tune a single specification or multiple specifications.

11. The method of claim 1, wherein creating a self-adapting analog circuit comprising several smaller circuits comprises:
creating a self-adapting analog circuit comprising several smaller circuits connected in a hierarchical manner by at least one of:
using hierarchical machine learning models comprising a top-level wrapper integrating the machine learning models of those smaller circuits according to certain priority or emphasis rules;
adjusting the top-level hierarchical machine learning model using hyper-parameter tuning for accuracy; and
using the hierarchical machine learning model to re-tune a single specification or multiple specifications.

12. A computer system for creating self-adapting analog circuits comprising a local workstation for user interface connected to a local disk containing local design data, a network cloud connecting the local workstation with a tool license server and a main compute server, a main compute server running all complex tasks of simulation, ML model creation, training, and verification, a main storage disk connected to the main server containing all design data including final netlist, simulation results, full query database, final ML model, sensor library, PMON library, circuit libraries, and reports and log files; wherein the computer system comprising:
a design entry and interface module residing in the local workstation to specify an analog micro-electronic circuit with a set of specifications;
a simulation test bench creator unit to create a simulation test bench applicable to the specific simulator based on an inputted simulation configuration and control directives;
a database builder to generate a full query database from simulation results that capture relationship between one or more of input conditions, output specification values, critical parameters of dominant components, process, voltage and temperature PVT over a complete range of PVT;
a sensitivity analyzer to generate a plurality of Pearson coefficients relating the input changes to the output changes under various PVT conditions;
a Machine Learning ML creator module to create a Machine Learning ML model based on the plurality of input and output specification variables to represent responses of an analog circuit to changes in the P, V, and T parameters; and
a self-adapted circuit netlist output module to create a self-adapting analog circuit by using the machine learning models to re-tune the output specification variables; wherein retuning the output specification variables comprises estimating using the ML model, values of the critical parameters of dominant components required to re-tune the specifications of the analog circuit to predetermined nominal values.

13. A computer system of claim 13, comprising of a combination of several or all of the following modules stored in its memory and called upon to build ML models for self-adapting analog circuits, the computer system comprises of:
a design entry and interface module to interface to the user and other design tools;
a simulator module to interface to an analog circuit simulator;
a dominant component checker unit to verify if dominant components picked by the user are valid or not;
a simulation test bench creator unit to create one or more test benches specified by the user for the analog circuit under test;
a query database builder to build full query database from simulation results to build the machine learning models;
a sensitivity analyzer unit to analyze the simulation results and formulate relationship between a plurality of critical parameters of the dominant components and the circuit specifications over pressure, voltage, temperature PVT parameters;
a Machine Learning ML model creator to create one or more ML models of the analog circuits according to one or more user-defined criteria's;
a Machine Learning ML training dataset builder to build training data and test data subsets for the ML models;
a Machine Learning ML model trainer to train the created ML models;
a Machine Learning ML model checker to check the accuracy of the ML models; and
a Machine Learning ML log and report generator to create and display log and report files per user instruction.

14. The computer system of claim 12, comprising of a combination of several or all of the following modules stored in its memory and called upon to build ML models for self-adapting analog circuits, the computer system further comprises of:
a configuration parser module to parse a configuration file in text format to separate and store the user inputs, system commands, simulation configurations, and output instructions related to the analog circuit being designed;
a netlist parser module to parse the netlist of the analog circuit text format to extract the information and instructions for simulation;
a simulator interface module to send and receive data and commands from the simulator;
a simulation measurement and calculation module to formulate the relationships between the inputs and outputs;
a ML model creation module to create an optimal ML model according to pre-set user-defined criteria's;
a ML prediction module to predict from the ML model output values according to an input type;
a test bench recreation module to create updated test benches for the self-adapting analog circuit updated with changes recommended through control data;
a design specific verifier to verify from simulation results that the self-adapted analog circuits according to the created control data to meet the required specifications; and
a self-adapted circuit netlist output module to generate a final netlist of the verified self-adapted analog circuit and the log files.
